(19) United States
(12) Patent Application Publication
(10) Pub. No.: US 2026/0278192 A1
(43) Pub. Date: Sep. 17, 2026

(54) Intelligent Floor-Level Workplace Occupancy and Utilization Detection

(71) Applicant: Zscaler, Inc., San Jose, CA (US)

(72) Inventors: Parth Ajaykumar Shah, San Jose, CA (US); Abhishek Bathla, Mohali (IN); Alok Kushwaha, San Jose, CA (US); Karthikeyan Selvarajan, Cupertino, CA (US); Nimish Gupta, Pleasanton, CA (US)

(73) Assignee: Zscaler, Inc., San Jose, CA (US)

(21) Appl. No.: 19/669,071

(22) Filed: May 6, 2026

Related U.S. Application Data
(63) Continuation-in-part of application No. 18/888,402, filed on Sep. 18, 2024.

(30) Foreign Application Priority Data
Aug. 6, 2024 (IN) 202441059308

(51) Int. Cl. G06F 30/13

(52) U.S. Cl. CPC G06F 30/13

(57) ABSTRACT

Systems and methods are disclosed for determining floor-level workplace occupancy using network telemetry. Wi-Fi change events associated with devices are received and enriched with office configuration data mapping wireless access points to physical floors. A probabilistic spatial inference engine converts signal quality values into weighted scores, aggregates scores by floor, and determines an inferred floor and confidence value. A temporal state management module validates inferred floor changes based on the confidence value and stored device state to filter noise and confirm location transitions. Confirmed changes update real-time and historical datastores to maintain aggregated floor-level occupancy counts. A machine learning module may adaptively update access point-to-floor mappings and generate predictive occupancy forecasts based on historical data. The system leverages existing network telemetry to provide scalable, privacy-centric, near-real-time and predictive workspace utilization insights without requiring additional physical occupancy sensors.

### CROSS-REFERENCE TO RELATED APPLICATION(S)

The present disclosure is a continuation-in-part of U.S. patent application Ser. No. 18/888,402, filed Sep. 18, 2024, entitled “Utilizing cloud-based data for determining and recommending organization office site locations,” the contents of which are incorporated by reference in their entirety.

### FIELD OF THE DISCLOSURE

The present disclosure relates generally to networking and computing. More particularly, the present disclosure relates to systems and methods for intelligent floor-level workplace occupancy and utilization detection.

### BACKGROUND OF THE DISCLOSURE

Enterprises invest substantial financial resources in corporate real estate, yet often lack accurate and timely visibility into how office spaces are actually utilized. Facility planners and operations teams frequently rely on manual surveys, badge data, or static assumptions to estimate occupancy, which provide limited granularity and are not well suited for real-time or floor-level analysis. As hybrid work models become more prevalent, understanding actual space utilization at a granular level, such as by floor and time of day, has become increasingly important for optimizing layouts, consolidating underused areas, supporting emergency response, and improving employee experience. Existing technical solutions, such as installing dedicated occupancy sensors, are costly to deploy and maintain across global office environments and may introduce operational complexity and privacy concerns. Simpler approaches that map a device's connected Wi-Fi access point directly to a floor are often unreliable due to signal overlap, device roaming behavior, and configuration inconsistencies. Accordingly, there remains a need for a scalable, cost-effective, and privacy-conscious system capable of accurately determining floor-level occupancy using infrastructure that is already deployed within enterprise networks.

### BRIEF SUMMARY OF THE DISCLOSURE

In an embodiment, systems and methods facilitate intelligent floor-level workplace occupancy and utilization detection using existing network telemetry. Wi-Fi change events generated by user devices are processed through an intelligent analytics engine that enriches telemetry with office configuration data, performs probabilistic floor inference using weighted signal strength analysis, and applies confidence-gated temporal validation to confirm stable device locations. Confirmed floor transitions are used to update real-time and historical occupancy datastores, enabling accurate, aggregated floor-level occupancy counts without deploying additional physical sensors. In certain embodiments, machine learning techniques are employed to adaptively update access point-to-floor mappings and to generate predictive occupancy forecasts based on historical utilization patterns. The system provides scalable, privacy-centric, near-real-time and predictive workspace analytics using infrastructure already deployed within an enterprise network environment.

In one aspect, a computer-implemented method is provided that includes receiving a Wi-Fi change event including device identification information and signal quality values for multiple visible access points; enriching the event with configuration data that maps access points to respective physical floors; determining an inferred floor and associated confidence score by applying a weighted signal-strength aggregation algorithm; and validating and updating a stored stable floor location based on the confidence score and a comparison with a previously stored location, and updating at least one occupancy datastore in response to a validated change.

In further aspects, the method may include applying a non-linear weighting function to signal quality values, filtering events below a confidence threshold, maintaining real-time and historical occupancy datastores, adaptively updating access point mappings using machine learning, and generating predictive floor-level occupancy forecasts. System and computer-readable medium embodiments corresponding to the foregoing method are also disclosed.

### BRIEF DESCRIPTION OF THE DRAWINGS

The present disclosure is illustrated and described herein with reference to the various drawings, in which like reference numbers are used to denote like system components/method steps, as appropriate, and in which:

FIG. 1A is a network diagram of a cloud-based system offering security as a service.

FIG. 1B is a logical diagram of the cloud-based system operating as a zero-trust platform.

FIG. 1C is a logical diagram illustrating zero trust policies with the cloud-based system and a comparison with the conventional firewall-based approach.

FIG. 2 is a network diagram of an example implementation of the cloud-based system.

FIG. 3 is a block diagram of a server, which may be used in the cloud-based system, in other systems, or standalone.

FIG. 4 is a block diagram of a user device, which may be used with the cloud-based system or the like.

FIG. 5 is a network diagram of a Zero Trust Network Access (ZTNA) application utilizing the cloud-based system.

FIG. 6 is a network diagram of the cloud-based system in an application of digital experience monitoring.

FIG. 7 is a screenshot of an exemplary business insights dashboard.

FIG. 8 is an example of application migration insights provided by the present systems and methods.

FIG. 9 is a graphical representation of productivity for a plurality of locations provided by the present systems and methods.

FIG. 10 is a graphical representation of productivity for a plurality of locations impacted by an organization-wide meeting.

FIG. 11 is a graphical representation of productivity for a plurality of locations impacted by an outage.

FIG. 12 is a graphical representation of office utilization provided by the present systems and methods.

FIG. 13 is a flowchart of a process for collecting and providing business insights for an organization.

FIG. 14 is a flow diagram for detecting office IP addresses.

FIG. 15 is a diagram of various users accessing the cloud-based system via various IPs including home IPs and office site IPs.

FIG. 16 is an example of an organization's user location data.

FIG. 17 is a flow diagram of a plurality of users utilizing a plurality of IPs for connecting to the cloud-based system.

FIG. 18 is a flowchart of a process for office site location determination and verification.

FIG. 19 is a flow diagram illustrating a high-level architectural of a system for intelligent floor-level workplace occupancy and utilization detection.

FIG. 20 is a flowchart of a process for determining floor-level workplace occupancy using network telemetry.

### DETAILED DESCRIPTION OF THE DISCLOSURE

Again, the present disclosure provides systems and methods for intelligent floor-level workplace occupancy and utilization detection using cloud-based network telemetry. In various embodiments, Wi-Fi change events associated with user devices are received and enriched with office configuration data that maps wireless access points to physical floors within an identified office site. A probabilistic spatial inference engine processes signal quality information from multiple visible access points to determine a most probable floor location for a device and generate an associated confidence score. A temporal state management module applies confidence-gated validation to confirm stable floor transitions and filter transient or noisy events. Confirmed location changes are used to update real-time and historical datastores to maintain aggregated floor-level occupancy counts.

In certain embodiments, Machine Learning (ML) techniques are employed to adaptively update access point-to-floor mappings and to generate predictive occupancy forecasts based on historical utilization patterns. The systems operate using existing cloud-based telemetry infrastructure, thereby providing scalable, privacy-centric, near-real-time, and predictive workspace utilization insights without requiring additional physical occupancy sensors.

Additionally, the present disclosure provides systems and methods for utilizing cloud-based data for determining and recommending organization office site locations. In various embodiments, the present processes facilitated by a cloud-based system include leveraging customer log data and live data to infer, recommend, and confirm office site locations from where their users/employees work. Various processes include inferring organization office site locations based on the data to provide organizations with an overview of their location distribution in an interactive User Interface (UI). Further, processes include determining the accuracy of current organization office site location databased to provide confirmation and/or update recommendations.

Cloud-based security solutions have emerged, such as Zscaler Internet Access (ZIA) and Zscaler Private Access (ZPA), available from Zscaler, Inc., the applicant and assignee of the present application. ZPA is a cloud service that provides seamless, zero trust access to private applications running on the public cloud, within the data center, within an enterprise network, etc. As described herein, ZPA is referred to as zero trust access to private applications or simply a zero trust access service. Here, applications are never exposed to the Internet, making them completely invisible to unauthorized users. The service enables the applications to connect to users via inside-out connectivity versus extending the network to them. Users are never placed on the network. This Zero Trust Network Access (ZTNA) approach supports both managed and unmanaged devices and any private application (not just web apps).

### Example Cloud-Based System Architecture

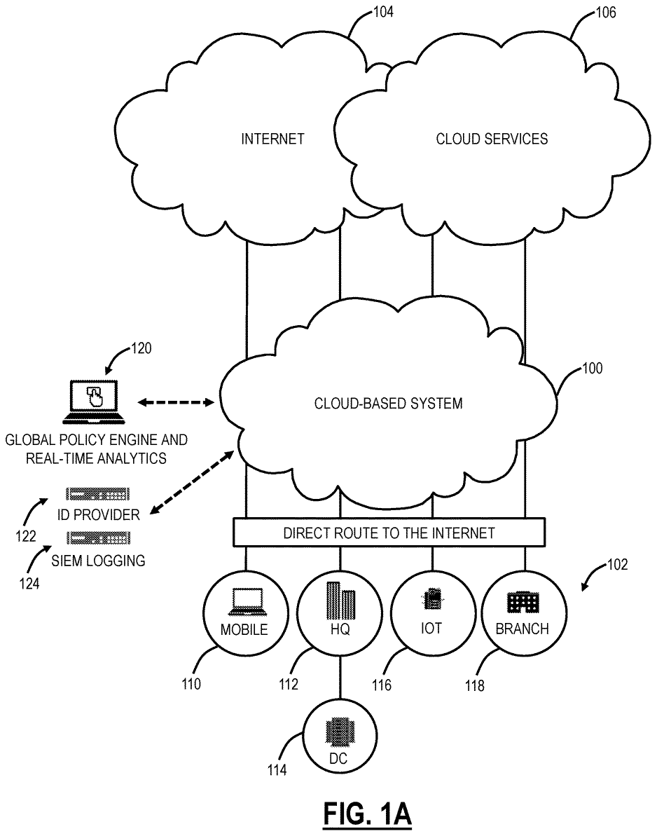

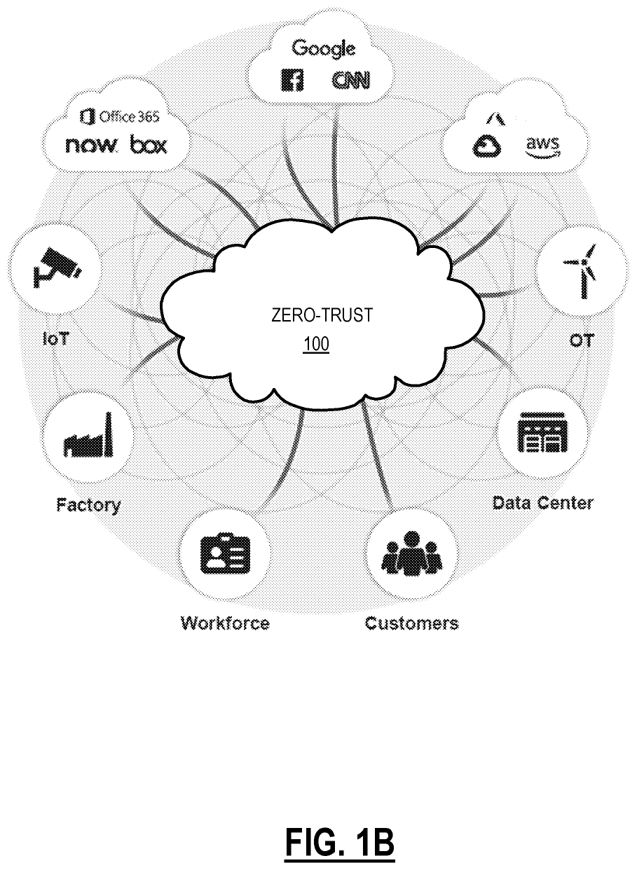

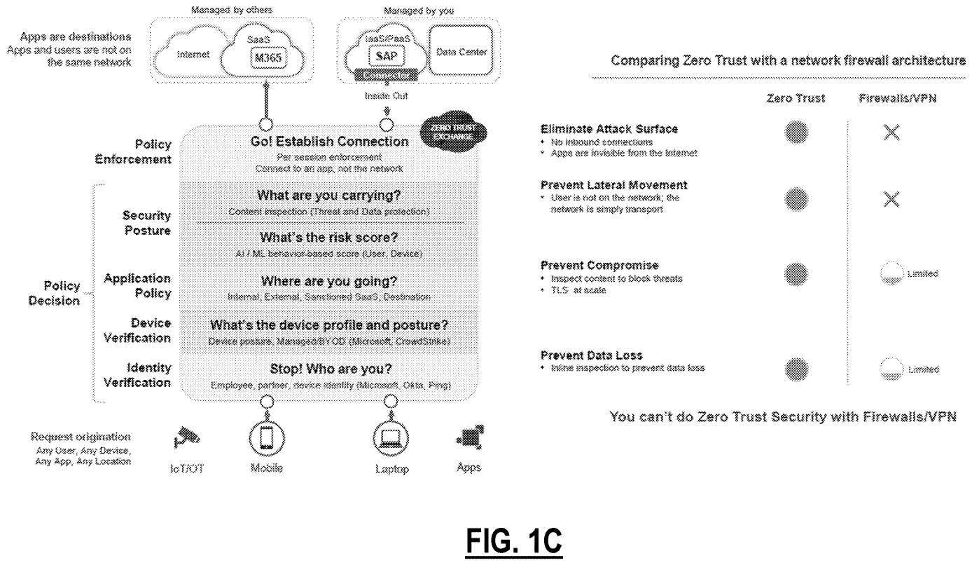

FIG. 1A is a network diagram of a cloud-based system 100 offering security as a service. Specifically, the cloud-based system 100 can offer a Secure Internet and Web Gateway as a service to various users 102, as well as other cloud services. In this manner, the cloud-based system 100 is located between the users 102 and the Internet as well as any cloud services 106 (or applications) accessed by the users 102. As such, the cloud-based system 100 provides inline monitoring inspecting traffic between the users 102, the Internet 104, and the cloud services 106, including Secure Sockets Layer (SSL) traffic. The cloud-based system 100 can offer access control, threat prevention, data protection, etc. The access control can include a cloud-based firewall, cloud-based intrusion detection, Uniform Resource Locator (URL) filtering, bandwidth control, Domain Name System (DNS) filtering, etc. The threat prevention can include cloud-based intrusion prevention, protection against advanced threats (malware, spam, Cross-Site Scripting (XSS), phishing, etc.), cloud-based sandbox, antivirus, DNS security, etc. The data protection can include Data Loss Prevention (DLP), cloud application security such as via a Cloud Access Security Broker (CASB), file type control, etc.

The cloud-based firewall can provide Deep Packet Inspection (DPI) and access controls across various ports and protocols as well as being application and user aware. The URL filtering can block, allow, or limit website access based on policy for a user, group of users, or entire organization, including specific destinations or categories of URLs (e.g., gambling, social media, etc.). The bandwidth control can enforce bandwidth policies and prioritize critical applications such as relative to recreational traffic. DNS filtering can control and block DNS requests against known and malicious destinations.

The cloud-based intrusion prevention and advanced threat protection can deliver full threat protection against malicious content such as browser exploits, scripts, identified botnets and malware callbacks, etc. The cloud-based sandbox can block zero-day exploits (just identified) by analyzing unknown files for malicious behavior. Advantageously, the cloud-based system 100 is multi-tenant and can service a large volume of the users 102. As such, newly discovered threats can be promulgated throughout the cloud-based system 100 for all tenants practically instantaneously. The antivirus protection can include antivirus, antispyware, antimalware, etc. protection for the users 102, using signatures sourced and constantly updated. The DNS security can identify and route command-and-control connections to threat detection engines for full content inspection.

The DLP can use standard and/or custom dictionaries to continuously monitor the users 102, including compressed and/or SSL-encrypted traffic. Again, being in a cloud implementation, the cloud-based system 100 can scale this monitoring with near-zero latency on the users 102. The cloud application security can include CASB functionality to discover and control user access to known and unknown cloud services 106. The file type controls enable true file type control by the user, location, destination, etc. to determine which files are allowed or not.

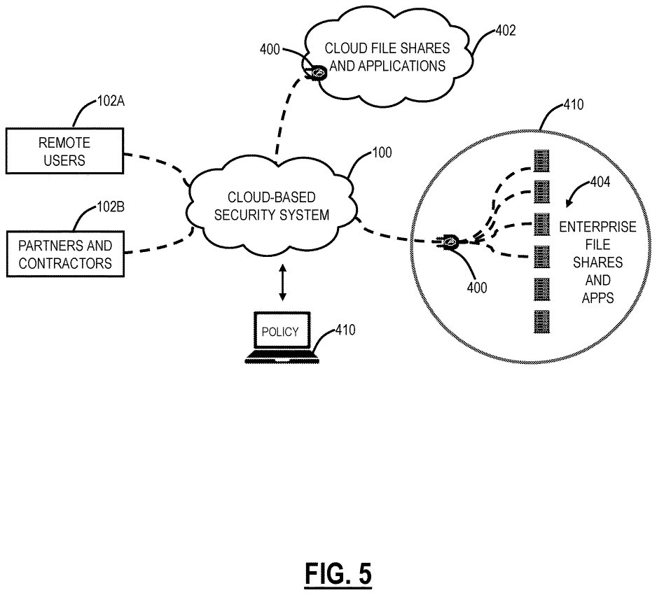

For illustration purposes, the users 102 of the cloud-based system 100 can include a mobile device 110, a headquarters (HQ) 112 which can include or connect to a data center (DC) 114, Internet of Things (IOT) devices 116, a branch office/remote location 118, etc., and each includes one or more user devices (an example user device 300 is illustrated in FIG. 5). The devices 110, 116, and the locations 112, 114, 118 are shown for illustrative purposes, and those skilled in the art will recognize there are various access scenarios and other users 102 for the cloud-based system 100, all of which are contemplated herein. The users 102 can be associated with a tenant, which may include an enterprise, a corporation, an organization, etc. That is, a tenant is a group of users who share a common access with specific privileges to the cloud-based system 100, a cloud service, etc. In an embodiment, the headquarters 112 can include an enterprise's network with resources in the data center 114. The mobile device 110 can be a so-called road warrior, i.e., users that are off-site, on-the-road, etc. Those skilled in the art will recognize a user 102 has to use a corresponding user device 300 for accessing the cloud-based system 100 and the like, and the description herein may use the user 102 and/or the user device 300 interchangeably.

Further, the cloud-based system 100 can be multi-tenant, with each tenant having its own users 102 and configuration, policy, rules, etc. One advantage of the multi-tenancy and a large volume of users is the zero-day/zero-hour protection in that a new vulnerability can be detected and then instantly remediated across the entire cloud-based system 100. The same applies to policy, rule, configuration, etc. changes-they are instantly remediated across the entire cloud-based system 100. As well, new features in the cloud-based system 100 can also be rolled up simultaneously across the user base, as opposed to selective and time-consuming upgrades on every device at the locations 112, 114, 118, and the devices 110, 116.

Logically, the cloud-based system 100 can be viewed as an overlay network between users (at the locations 112, 114, 118, and the devices 110, 116) and the Internet 104 and the cloud services 106. Previously, the IT deployment model included enterprise resources and applications stored within the data center 114 (i.e., physical devices) behind a firewall (perimeter), accessible by employees, partners, contractors, etc. on-site or remote via Virtual Private Networks (VPNs), etc. The cloud-based system 100 is replacing the conventional deployment model. The cloud-based system 100 can be used to implement these services in the cloud without requiring the physical devices and management thereof by enterprise IT administrators. As an ever-present overlay network, the cloud-based system 100 can provide the same functions as the physical devices and/or appliances regardless of geography or location of the users 102, as well as independent of platform, operating system, network access technique, network access provider, etc.

There are various techniques to forward traffic between the users 102 at the locations 112, 114, 118, and via the devices 110, 116, and the cloud-based system 100.

Typically, the locations 112, 114, 118 can use tunneling where all traffic is forward through the cloud-based system 100. For example, various tunneling protocols are contemplated, such as Generic Routing Encapsulation (GRE), Layer Two Tunneling Protocol (L2TP), Internet Protocol (IP) Security (IPsec), customized tunneling protocols, etc. The devices 110, 116, when not at one of the locations 112, 114, 118 can use a local application that forwards traffic, a proxy such as via a Proxy Auto-Config (PAC) file, and the like. An application of the local application is the application 350 described in detail herein as a connector application. A key aspect of the cloud-based system 100 is all traffic between the users 102 and the Internet 104 or the cloud services 106 is via the cloud-based system 100. As such, the cloud-based system 100 has visibility to enable various functions, all of which are performed off the user device in the cloud.

The cloud-based system 100 can also include a management system 120 for tenant access to provide global policy and configuration as well as real-time analytics. This enables IT administrators to have a unified view of user activity, threat intelligence, application usage, etc. For example, IT administrators can drill-down to a per-user level to understand events and correlate threats, to identify compromised devices, to have application visibility, and the like. The cloud-based system 100 can further include connectivity to an Identity Provider (IDP) 122 for authentication of the users 102 and to a Security Information and Event Management (SIEM) system 124 for event logging. The system 124 can provide alert and activity logs on a per-user 102 basis.

### Zero Trust

FIG. 1B is a logical diagram of the cloud-based system 100 operating as a zero-trust platform. Zero trust is a framework for securing organizations in the cloud and mobile world that asserts that no user or application should be trusted by default. Following a key zero trust principle, least-privileged access, trust is established based on context (e.g., user identity and location, the security posture of the endpoint, the app or service being requested) with policy checks at each step, via the cloud-based system 100. Zero trust is a cybersecurity strategy wherein security policy is applied based on context established through least-privileged access controls and strict user authentication—not assumed trust. A well-tuned zero trust architecture leads to simpler network infrastructure, a better user experience, and improved cyberthreat defense.

Establishing a zero trust architecture requires visibility and control over the environment's users and traffic, including that which is encrypted; monitoring and verification of traffic between parts of the environment; and strong multifactor authentication (MFA) methods beyond passwords, such as biometrics or one-time codes. This is performed via the cloud-based system 100. Critically, in a zero trust architecture, a resource's network location is not the biggest factor in its security posture anymore. Instead of rigid network segmentation, your data, workflows, services, and such are protected by software-defined microsegmentation, enabling you to keep them secure anywhere, whether in your data center or in distributed hybrid and multicloud environments.

The core concept of zero trust is simple: assume everything is hostile by default. It is a major departure from the network security model built on the centralized data center and secure network perimeter. These network architectures rely on approved IP addresses, ports, and protocols to establish access controls and validate what's trusted inside the network, generally including anybody connecting via remote access VPN. In contrast, a zero trust approach treats all traffic, even if it is already inside the perimeter, as hostile. For example, workloads are blocked from communicating until they are validated by a set of attributes, such as a fingerprint or identity. Identity-based validation policies result in stronger security that travels with the workload wherever it communicates—in a public cloud, a hybrid environment, a container, or an on-premises network architecture.

Because protection is environment-agnostic, zero trust secures applications and services even if they communicate across network environments, requiring no architectural changes or policy updates. Zero trust securely connects users, devices, and applications using business policies over any network, enabling safe digital transformation. Zero trust is about more than user identity, segmentation, and secure access. It is a strategy upon which to build a cybersecurity ecosystem.

At its core are three tenets:
Terminate every connection: Technologies like firewalls use a “passthrough” approach, inspecting files as they are delivered. If a malicious file is detected, alerts are often too late. An effective zero trust solution terminates every connection to allow an inline proxy architecture to inspect all traffic, including encrypted traffic, in real time—before it reaches its destination—to prevent ransomware, malware, and more.
Protect data using granular context-based policies: Zero trust policies verify access requests and rights based on context, including user identity, device, location, type of content, and the application being requested. Policies are adaptive, so user access privileges are continually reassessed as context changes.
Reduce risk by eliminating the attack surface: With a zero trust approach, users connect directly to the apps and resources they need, never to networks (see ZTNA). Direct user-to-app and app-to-app connections eliminate the risk of lateral movement and prevent compromised devices from infecting other resources. Plus, users and apps are invisible to the internet, so they cannot be discovered or attacked.

FIG. 1C is a logical diagram illustrating zero trust policies with the cloud-based system 100 and a comparison with the conventional firewall-based approach. Zero trust with the cloud-based system 100 allows per session policy decisions and enforcement regardless of the user 102 location. Unlike the conventional firewall-based approach, this eliminates attack surfaces, there are no inbound connections; prevents lateral movement, the user is not on the network; prevents compromise, allowing encrypted inspection; and prevents data loss with inline inspection.

### Example Implementation of the Cloud-Based System

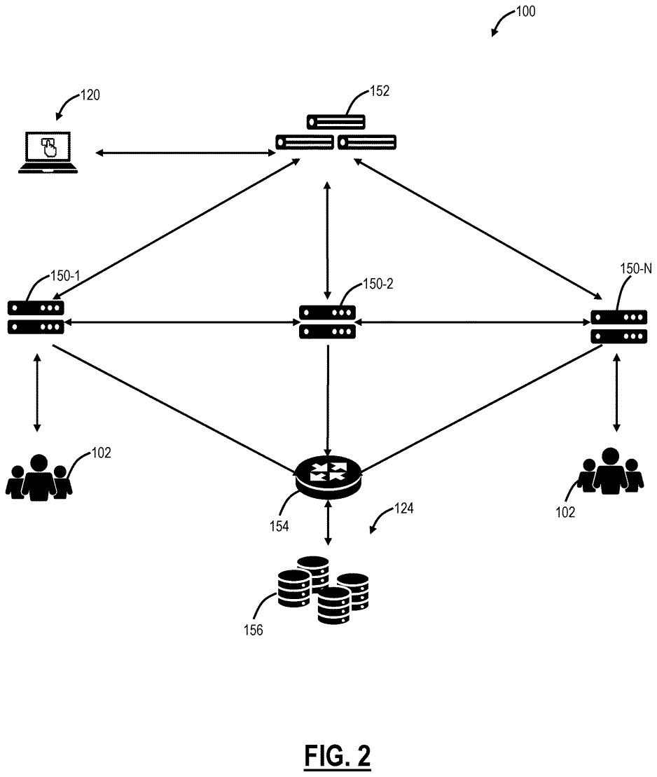

FIG. 2 is a network diagram of an example implementation of the cloud-based system 100. In an embodiment, the cloud-based system 100 includes a plurality of nodes 150, labeled as nodes 150-1, 150-2, 150-N, interconnected to one another and interconnected to a central authority (CA) 152. The nodes 150 and the central authority 152, while described as nodes, can include one or more servers, including physical servers, virtual machines (VM) executed on physical hardware, etc. An example of a server is illustrated in FIG. 4. The cloud-based system 100 further includes a log router 154 that connects to a storage cluster 156 for supporting log maintenance from the nodes 150. The central authority 152 provide centralized policy, real-time threat updates, etc. and coordinates the distribution of this data between the nodes 150. The nodes 150 provide an onramp to the users 102 and are configured to execute policy, based on the central authority 152, for each user 102. The nodes 150 can be geographically distributed, and the policy for each user 102 follows that user 102 as he or she connects to the nearest (or other criteria) node 150.

Of note, the cloud-based system 100 is an external system meaning it is separate from tenant's private networks (enterprise networks) as well as from networks associated with the devices 110, 116, and locations 112, 118. Also, of note, the present disclosure describes a private node 150P that is both part of the cloud-based system 100 and part of a private network. Further, of note, the node described herein may simply be referred to as a node or cloud node. Also, the terminology node 150 is used in the context of the cloud-based system 100 providing cloud-based security. In the context of secure, private application access, the node 150 can also be referred to as a service edge or service edge node. Also, a service edge node 150 can be a public service edge node (part of the cloud-based system 100) separate from an enterprise network or a private service edge node (still part of the cloud-based system 100) but hosted either within an enterprise network, in a data center 114, in a branch office 118, etc. Further, the term nodes as used herein with respect to the cloud-based system 100 (including nodes, service edge nodes, etc.) can be one or more servers, including physical servers, virtual machines (VM) executed on physical hardware, etc., as described above. The service edge node 150 can also be a Secure Access Service Edge (SASE).

The nodes 150 are full-featured secure internet gateways that provide integrated internet security. They inspect all web traffic bi-directionally for malware and enforce security, compliance, and firewall policies, as described herein, as well as various additional functionality. In an embodiment, each node 150 has two main modules for inspecting traffic and applying policies: a web module and a firewall module. The nodes 150 are deployed around the world and can handle hundreds of thousands of concurrent users with millions of concurrent sessions. Because of this, regardless of where the users 102 are, they can access the Internet 104 from any device, and the nodes 150 protect the traffic and apply corporate policies. The nodes 150 can implement various inspection engines therein, and optionally, send sandboxing to another system. The nodes 150 include significant fault tolerance capabilities, such as deployment in active-active mode to ensure availability and redundancy as well as continuous monitoring.

In an embodiment, customer traffic is not passed to any other component within the cloud-based system 100, and the nodes 150 can be configured never to store any data to disk. Packet data is held in memory for inspection and then, based on policy, is either forwarded or dropped. Log data generated for every transaction is compressed, tokenized, and exported over secure Transport Layer Security (TLS) connections to the log routers 154 that direct the logs to the storage cluster 156, hosted in the appropriate geographical region, for each organization. In an embodiment, all data destined for or received from the Internet is processed through one of the nodes 150. In another embodiment, specific data specified by each tenant, e.g., only email, only executable files, etc., is processed through one of the nodes 150.

Each of the nodes 150 may generate a decision vector D=[d1, d2, . . . , dn] for a content item of one or more parts C=[c1, c2, . . . , cm]. Each decision vector may identify a threat classification, e.g., clean, spyware, malware, undesirable content, innocuous, spam email, unknown, etc. For example, the output of each element of the decision vector D may be based on the output of one or more data inspection engines. In an embodiment, the threat classification may be reduced to a subset of categories, e.g., violating, non-violating, neutral, unknown. Based on the subset classification, the node 150 may allow the distribution of the content item, preclude distribution of the content item, allow distribution of the content item after a cleaning process, or perform threat detection on the content item. In an embodiment, the actions taken by one of the nodes 150 may be determinative on the threat classification of the content item and on a security policy of the tenant to which the content item is being sent from or from which the content item is being requested by. A content item is violating if, for any part C=[c1, c2, . . . , cm] of the content item, at any of the nodes 150, any one of the data inspection engines generates an output that results in a classification of “violating.”

The central authority 152 hosts all customer (tenant) policy and configuration settings. It monitors the cloud and provides a central location for software and database updates and threat intelligence. Given the multi-tenant architecture, the central authority 152 is redundant and backed up in multiple different data centers. The nodes 150 establish persistent connections to the central authority 152 to download all policy configurations. When a new user connects to a node 150, a policy request is sent to the central authority 152 through this connection. The central authority 152 then calculates the policies that apply to that user 102 and sends the policy to the node 150 as a highly compressed bitmap.

The policy can be tenant-specific and can include access privileges for users, websites and/or content that is disallowed, restricted domains, DLP dictionaries, etc. Once downloaded, a tenant's policy is cached until a policy change is made in the management system 120. The policy can be tenant-specific and can include access privileges for users, websites and/or content that is disallowed, restricted domains, DLP dictionaries, etc. When this happens, all of the cached policies are purged, and the nodes 150 request the new policy when the user 102 next makes a request. In an embodiment, the node 150 exchange “heartbeats” periodically, so all nodes 150 are informed when there is a policy change. Any node 150 can then pull the change in policy when it sees a new request.

The cloud-based system 100 can be a private cloud, a public cloud, a combination of a private cloud and a public cloud (hybrid cloud), or the like. Cloud computing systems and methods abstract away physical servers, storage, networking, etc., and instead offer these as on-demand and elastic resources. The National Institute of Standards and Technology (NIST) provides a concise and specific definition which states cloud computing is a model for enabling convenient, on-demand network access to a shared pool of configurable computing resources (e.g., networks, servers, storage, applications, and services) that can be rapidly provisioned and released with minimal management effort or service provider interaction. Cloud computing differs from the classic client-server model by providing applications from a server that are executed and managed by a client's web browser or the like, with no installed client version of an application required. Centralization gives cloud service providers complete control over the versions of the browser-based and other applications provided to clients, which removes the need for version upgrades or license management on individual client computing devices. The phrase “Software as a Service” (SaaS) is sometimes used to describe application programs offered through cloud computing. A common shorthand for a provided cloud computing service (or even an aggregation of all existing cloud services) is “the cloud.” The cloud-based system 100 is illustrated herein as an example embodiment of a cloud-based system, and other implementations are also contemplated.

As described herein, the terms cloud services and cloud applications may be used interchangeably. The cloud service 106 is any service made available to users on-demand via the Internet, as opposed to being provided from a company's on-premises servers. A cloud application, or cloud app, is a software program where cloud-based and local components work together. The cloud-based system 100 can be utilized to provide example cloud services, including Zscaler Internet Access (ZIA), Zscaler Private Access (ZPA), and Zscaler Digital Experience (ZDX), all from Zscaler, Inc. (the assignee and applicant of the present application). Also, there can be multiple different cloud-based systems 100, including ones with different architectures and multiple cloud services. The ZIA service can provide the access control, threat prevention, and data protection described above with reference to the cloud-based system 100. ZPA can include access control, microservice segmentation, etc. The ZDX service can provide monitoring of user experience, e.g., Quality of Experience (QoE), Quality of Service (QoS), etc., in a manner that can gain insights based on continuous, inline monitoring. For example, the ZIA service can provide a user with Internet Access, and the ZPA service can provide a user with access to enterprise resources instead of traditional Virtual Private Networks (VPNs), namely ZPA provides Zero Trust Network Access (ZTNA). Those of ordinary skill in the art will recognize various other types of cloud services 106 are also contemplated. Also, other types of cloud architectures are also contemplated, with the cloud-based system 100 presented for illustration purposes.

### Example Server Architecture

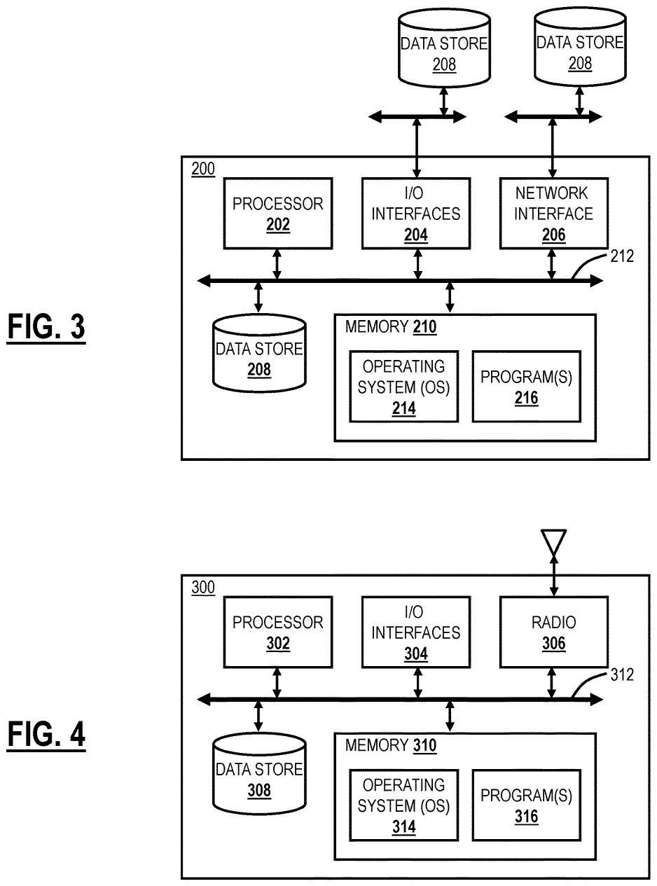

FIG. 3 is a block diagram of a server 200, which may be used in the cloud-based system 100, in other systems, or standalone. For example, the nodes 150 and the central authority 152 may be formed as one or more of the servers 200. The server 200 may be a digital computer that, in terms of hardware architecture, generally includes a processor 202, input/output (I/O) interfaces 204, a network interface 206, a data store 208, and memory 210. It should be appreciated by those of ordinary skill in the art that FIG. 3 depicts the server 200 in an oversimplified manner, and a practical embodiment may include additional components and suitably configured processing logic to support known or conventional operating features that are not described in detail herein. The components (202, 204, 206, 208, and 210) are communicatively coupled via a local interface 212. The local interface 212 may be, for example, but not limited to, one or more buses or other wired or wireless connections, as is known in the art. The local interface 212 may have additional elements, which are omitted for simplicity, such as controllers, buffers (caches), drivers, repeaters, and receivers, among many others, to enable communications. Further, the local interface 212 may include address, control, and/or data connections to enable appropriate communications among the aforementioned components.

The processor 202 is a hardware device for executing software instructions. The processor 202 may be any custom made or commercially available processor, a Central Processing Unit (CPU), an auxiliary processor among several processors associated with the server 200, a semiconductor-based microprocessor (in the form of a microchip or chipset), or generally any device for executing software instructions. When the server 200 is in operation, the processor 202 is configured to execute software stored within the memory 210, to communicate data to and from the memory 210, and to generally control operations of the server 200 pursuant to the software instructions. The I/O interfaces 204 may be used to receive user input from and/or for providing system output to one or more devices or components.

The network interface 206 may be used to enable the server 200 to communicate on a network, such as the Internet 104. The network interface 206 may include, for example, an Ethernet card or adapter or a Wireless Local Area Network (WLAN) card or adapter. The network interface 206 may include address, control, and/or data connections to enable appropriate communications on the network. A data store 208 may be used to store data. The data store 208 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof.

Moreover, the data store 208 may incorporate electronic, magnetic, optical, and/or other types of storage media. In one example, the data store 208 may be located internal to the server 200, such as, for example, an internal hard drive connected to the local interface 212 in the server 200. Additionally, in another embodiment, the data store 208 may be located external to the server 200 such as, for example, an external hard drive connected to the I/O interfaces 204 (e.g., SCSI or USB connection). In a further embodiment, the data store 208 may be connected to the server 200 through a network, such as, for example, a network-attached file server.

The memory 210 may include any of volatile memory elements (e.g., random access memory (RAM, such as DRAM, SRAM, SDRAM, etc.)), nonvolatile memory elements (e.g., ROM, hard drive, tape, CDROM, etc.), and combinations thereof. Moreover, the memory 210 may incorporate electronic, magnetic, optical, and/or other types of storage media. Note that the memory 210 may have a distributed architecture, where various components are situated remotely from one another but can be accessed by the processor 202. The software in memory 210 may include one or more software programs, each of which includes an ordered listing of executable instructions for implementing logical functions. The software in the memory 210 includes a suitable Operating System (O/S) 214 and one or more programs 216. The operating system 214 essentially controls the execution of other computer programs, such as the one or more programs 216, and provides scheduling, input-output control, file and data management, memory management, and communication control and related services. The one or more programs 216 may be configured to implement the various processes, algorithms, methods, techniques, etc. described herein.

### Example User Device Architecture

FIG. 4 is a block diagram of a user device 300, which may be used with the cloud-based system 100 or the like. Specifically, the user device 300 can form a device used by one of the users 102, and this may include common devices such as laptops, smartphones, tablets, netbooks, personal digital assistants, MP3 players, cell phones, e-book readers, IOT devices, servers, desktops, printers, televisions, streaming media devices, and the like. The user device 300 can be a digital device that, in terms of hardware architecture, generally includes a processor 302, I/O interfaces 304, a network interface 306, a data store 308, and memory 310. It should be appreciated by those of ordinary skill in the art that FIG. 4 depicts the user device 300 in an oversimplified manner, and a practical embodiment may include additional components and suitably configured processing logic to support known or conventional operating features that are not described in detail herein. The components (302, 304, 306, 308, and 302) are communicatively coupled via a local interface 312. The local interface 312 can be, for example, but not limited to, one or more buses or other wired or wireless connections, as is known in the art. The local interface 312 can have additional elements, which are omitted for simplicity, such as controllers, buffers (caches), drivers, repeaters, and receivers, among many others, to enable communications. Further, the local interface 312 may include address, control, and/or data connections to enable appropriate communications among the aforementioned components.

The processor 302 is a hardware device for executing software instructions. The processor 302 can be any custom made or commercially available processor, a CPU, an auxiliary processor among several processors associated with the user device 300, a semiconductor-based microprocessor (in the form of a microchip or chipset), or generally any device for executing software instructions. When the user device 300 is in operation, the processor 302 is configured to execute software stored within the memory 310, to communicate data to and from the memory 310, and to generally control operations of the user device 300 pursuant to the software instructions. In an embodiment, the processor 302 may include a mobile optimized processor such as optimized for power consumption and mobile applications. The I/O interfaces 304 can be used to receive user input from and/or for providing system output. User input can be provided via, for example, a keypad, a touch screen, a scroll ball, a scroll bar, buttons, a barcode scanner, and the like. System output can be provided via a display device such as a Liquid Crystal Display (LCD), touch screen, and the like.

The network interface 306 enables wireless communication to an external access device or network. Any number of suitable wireless data communication protocols, techniques, or methodologies can be supported by the network interface 306, including any protocols for wireless communication. The data store 308 may be used to store data. The data store 308 may include any of volatile memory elements (e.g., random access memory (RAM, such as DRAM, SRAM, SDRAM, and the like)), nonvolatile memory elements (e.g., ROM, hard drive, tape, CDROM, and the like), and combinations thereof. Moreover, the data store 308 may incorporate electronic, magnetic, optical, and/or other types of storage media.

The memory 310 may include any of volatile memory elements (e.g., random access memory (RAM, such as DRAM, SRAM, SDRAM, etc.)), nonvolatile memory elements (e.g., ROM, hard drive, etc.), and combinations thereof. Moreover, the memory 310 may incorporate electronic, magnetic, optical, and/or other types of storage media. Note that the memory 310 may have a distributed architecture, where various components are situated remotely from one another but can be accessed by the processor 302. The software in memory 310 can include one or more software programs, each of which includes an ordered listing of executable instructions for implementing logical functions. In the example of FIG. 3, the software in the memory 310 includes a suitable operating system 314 and programs 316. The operating system 314 essentially controls the execution of other computer programs and provides scheduling, input-output control, file and data management, memory management, and communication control and related services. The programs 316 may include various applications, add-ons, etc. configured to provide end user functionality with the user device 300. For example, example programs 316 may include, but not limited to, a web browser, social networking applications, streaming media applications, games, mapping and location applications, electronic mail applications, financial applications, and the like. In a typical example, the end-user typically uses one or more of the programs 316 along with a network such as the cloud-based system 100.

### Zero Trust Network Access Using the Cloud-Based System

FIG. 5 is a network diagram of a Zero Trust Network Access (ZTNA) application utilizing the cloud-based system 100. For ZTNA, the cloud-based system 100 can dynamically create a connection through a secure tunnel between an endpoint (e.g., users 102A, 102B) that are remote and an on-premises connector 400 that is either located in cloud file shares and applications 402 and/or in an enterprise network 410 that includes enterprise file shares and applications 404. The connection between the cloud-based system 100 and on-premises connector 400 is dynamic, on-demand, and orchestrated by the cloud-based system 100. A key feature is its security at the edge—there is no need to punch any holes in the existing on-premises firewall. The connector 400 inside the enterprise (on-premises) “dials out” and connects to the cloud-based system 100 as if too were an endpoint. This on-demand dial-out capability and tunneling authenticated traffic back to the enterprise is a key differentiator for ZTNA. Also, this functionality can be implemented in part by an application 350 on the user device 300. Also, the applications 402, 404 can include B2B applications. Note, the difference between the applications 402, 404 is the applications 402 are hosted in the cloud, whereas the applications 404 are hosted on the enterprise network 410. The services described herein contemplates use with either or both of the applications 402, 404.

The paradigm of virtual private access systems and methods is to give users network access to get to an application and/or file share, not to the entire network. If a user is not authorized to get the application, the user should not be able even to see that it exists, much less access it. The virtual private access systems and methods provide an approach to deliver secure access by decoupling applications 402, 404 from the network, instead of providing access with a connector 400, in front of the applications 402, 404, an application on the user device 300, a central authority 152 to push policy, and the cloud-based system 100 to stitch the applications 402, 404 and the software connectors 400 together, on a per-user, per-application basis.

With the virtual private access, users can only see the specific applications 402, 404 allowed by the central authority 152. Everything else is “invisible” or “dark” to them. Because the virtual private access separates the application from the network, the physical location of the application 402, 404 becomes irrelevant-if applications 402, 404 are located in more than one place, the user is automatically directed to the instance that will give them the best performance. The virtual private access also dramatically reduces configuration complexity, such as policies/firewalls in the data centers. Enterprises can, for example, move applications to Amazon Web Services or Microsoft Azure, and take advantage of the elasticity of the cloud, making private, internal applications behave just like the marketing leading enterprise applications. Advantageously, there is no hardware to buy or deploy because the virtual private access is a service offering to end-users and enterprises.

### Digital Experience Monitoring

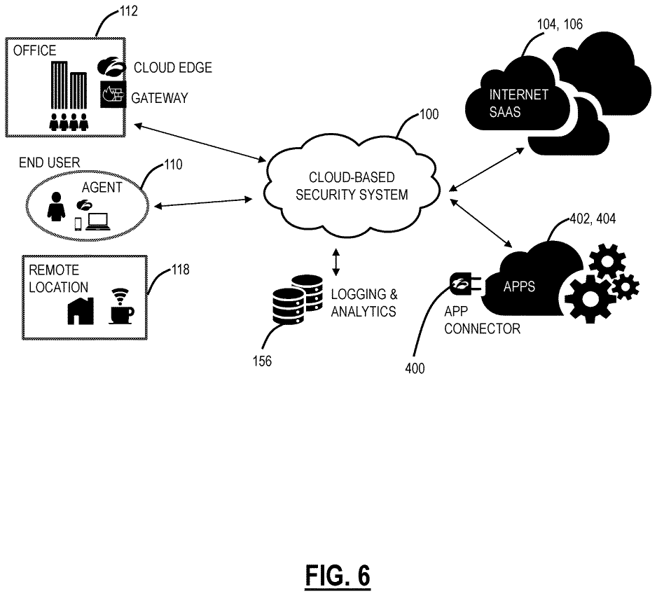

FIG. 6 is a network diagram of the cloud-based system 100 in an application of digital experience monitoring. Here, the cloud-based system 100 providing security as a service as well as ZTNA, can also be used to provide real-time, continuous digital experience monitoring, as opposed to conventional approaches (synthetic probes). A key aspect of the architecture of the cloud-based system 100 is the inline monitoring. This means data is accessible in real-time for individual users from end-to-end. As described herein, digital experience monitoring can include monitoring, analyzing, and improving the digital user experience.

The cloud-based system 100 connects users 102 at the locations 110, 112, 118 to the applications 402, 404, the Internet 104, the cloud services 106, etc. The inline, end-to-end visibility of all users enables digital experience monitoring. The cloud-based system 100 can monitor, diagnose, generate alerts, and perform remedial actions with respect to network endpoints, network components, network links, etc. The network endpoints can include servers, virtual machines, containers, storage systems, or anything with an IP address, including the Internet of Things (IoT), cloud, and wireless endpoints. With these components, these network endpoints can be monitored directly in combination with a network perspective. Thus, the cloud-based system 100 provides a unique architecture that can enable digital experience monitoring, network application monitoring, infrastructure component interactions, etc. Of note, these various monitoring aspects require no additional components—the cloud-based system 100 leverages the existing infrastructure to provide this service.

Again, digital experience monitoring includes the capture of data about how end-to-end application availability, latency, and quality appear to the end user from a network perspective. This is limited to the network traffic visibility and not within components, such as what application performance monitoring can accomplish. Networked application monitoring provides the speed and overall quality of networked application delivery to the user in support of key business activities. Infrastructure component interactions include a focus on infrastructure components as they interact via the network, as well as the network delivery of services or applications. This includes the ability to provide network path analytics.

The cloud-based system 100 can enable real-time performance and behaviors for troubleshooting in the current state of the environment, historical performance and behaviors to understand what occurred or what is trending over time, predictive behaviors by leveraging analytics technologies to distill and create actionable items from the large dataset collected across the various data sources, and the like. The cloud-based system 100 includes the ability to directly ingest any of the following data sources network device-generated health data, network device-generated traffic data, including flow-based data sources inclusive of NetFlow and IPFIX, raw network packet analysis to identify application types and performance characteristics, HTTP request metrics, etc. The cloud-based system 100 can operate at 10 gigabits (10G) Ethernet and higher at full line rate and support a rate of 100,000 or more flows per second or higher.

The applications 402, 404 can include enterprise applications, Office 365, Salesforce, Skype, Google apps, internal applications, etc. These are critical business applications where user experience is important. The objective here is to collect various data points so that user experience can be quantified for a particular user, at a particular time, for purposes of analyzing the experience as well as improving the experience. In an embodiment, the monitored data can be from different categories, including application-related, network-related, device-related (also can be referred to as endpoint-related), protocol-related, etc. Data can be collected at the application 350 or the cloud edge to quantify user experience for specific applications, i.e., the application-related and device-related data. The cloud-based system 100 can further collect the network-related and the protocol-related data (e.g., Domain Name System (DNS) response time).

### Application-Related Data

| Page Load Time | Redirect count (#) |
|---|---|
| Page Response Time | Throughput (bps) |
| Document Object Model (DOM) | Total size (bytes) |
| Load Time | |
| Total Downloaded bytes | Page error count (#) |
| App availability (%) | Page element count by category (#) |

### Network-Related Data

| HTTP Request metrics | Bandwidth |
|---|---|
| Server response time | Jitter |
| Ping packet loss (%) | Trace Route |
| Ping round trip | DNS lookup trace |
| Packet loss (%) | GRE/IPSec tunnel monitoring |
| Latency | MTU and bandwidth measurements |

### Device-Related Data (Endpoint-Related Data)

| System details | Network (config) |
|---|---|
| Central Processing Unit (CPU) | Disk |
| Memory (RAM) | Processes |
| Network (interfaces) | Applications |

Metrics could be combined. For example, device health can be based on a combination of CPU, memory, etc. Network health could be a combination of Wi-Fi/LAN connection health, latency, etc. Application health could be a combination of response time, page loads, etc. The cloud-based system 100 can generate service health as a combination of CPU, memory, and the load time of the service while processing a user's request. The network health could be based on the number of network path(s), latency, packet loss, etc.

The lightweight connector 400 can also generate similar metrics for the applications 402, 404. In an embodiment, the metrics can be collected while a user is accessing specific applications that user experience is desired for monitoring. In another embodiment, the metrics can be enriched by triggering synthetic measurements in the context of an inline transaction by the application 350 or cloud edge. The metrics can be tagged with metadata (user, time, app, etc.) and sent to a logging and analytics service for aggregation, analysis, and reporting. Further, network administrators can get UEX reports from the cloud-based system 100. Due to the inline nature and the fact the cloud-based system 100 is an overlay (in-between users and services/applications), the cloud-based system 100 enables the ability to capture user experience metric data continuously and to log such data historically. As such, a network administrator can have a long-term detailed view of the network and associated user experience.

### Business Insights

The present disclosure provides systems and methods for collecting and processing data to provide insights into applications, infrastructure, and an employee base associated with organizations which leverage the cloud-based system, such as the cloud-based system 100 described herein. In various embodiments, the systems and methods can provide actionable insights which can allow organizations to understand their application landscape, spend, and usage. Further, such systems and methods can help organizations discover savings opportunities, for example, by discovering unused licenses. Various exemplary use cases can include infrastructure optimization, i.e., providing insights to help determine if there are certain sites that can be closed or any sights that need more bandwidth for uplinks, etc. In a further use case, the systems and methods can be utilized for visualizing employee productivity, i.e., helping to determine which groups of employees collaborate the most with each other, etc.

The insights can be leveraged by organizations to make more effective decisions around SaaS and location consolidation, driving a return to work strategy, and understanding how and where teams are communicating so that they can drive business process optimization (e.g. removing silos, consolidating tools, improving support response times, etc.). These areas of application insights, infrastructure insights and workforce insights are described herein.

By utilizing the present systems and methods, organizations can have a greater understanding of their infrastructure and employees for optimizing operational efficiency. The present invention can answer questions which are important for optimizing an organization. These questions can include, but are not limited to, what applications does the organization have? Are they being utilized? By whom? How often? Are there cost savings and efficiencies to be found in the application stack and licensing agreements? It can also be beneficial to understand if an organization's working model is performing well. That includes, for example, providing insights for how a hybrid work environment is impacting productivity in an organization. Further, the present systems and methods can improve an organizations performance by identifying any unsanctioned applications being utilized by top performers and identifying any opportunities to adopt new applications or services that can accelerate innovation and efficiency. Even further, based on the data available to the cloud-based system, various embodiments of the present systems and methods can allow organizations to gain a better understanding of where their employees are located, if they are working in an office location associated with the organization, and visualize an organizations office locations.

SaaS applications have become ubiquitous in most organizations today. Studies have revealed that companies employing 2,000 or more individuals maintained an inventory of 175 SaaS applications on average. The trend towards SaaS applications has resulted in a large and often unconstrained sprawl of solutions and vendors in many organizations that leads to unnecessary expenses. There is a need to optimize SaaS spend and look for a simple solution that can provide answers with minimal effort. Existing solutions require significant manual effort to configure integrations with SaaS application vendors and require manual data entry. IT budget owners and procurement managers do not have access to configure integrations to pull usage data from SaaS vendors and, without usage data, the tool fails to answer basic questions to help rightsized licenses.

Companies are driving a return to work strategy but are blind to how many people are actually in the office. Organizations rely on traditional badging services, but these do not account for tailgating and/or smaller branch use cases where badging data is not always available. By utilizing the various features described herein, as well as the ability to perform a MaxMind GeoIP lookup and use digital experience monitoring location services, it is possible to infer an office location and also provide rich reports on where a company is in its return to work strategy, along with detailed breakdowns on in-office occupancy, hybrid work, and remote workers (along with city, state and country distributions and trends over time, which can then be used to decide where offices could be opened or closed).

It is also important for organizations to track employee collaboration, productivity, and well-being. Traditional solutions can provide this to a certain extent but are limited to their specific ecosystem. The present solution can utilize rich data leveraging the various cloud technologies (ZIA, ZDX, etc.) as well as CASB integrations to provide detailed collaboration insights such as who is talking to who, using which tools, at a location, department, or individual level. By using the present systems and methods, digital workplace and Human Resources (HR) teams can answer key questions like which departments are siloed, what are the most popular tools, and is there tool sprawl? Is there room for business process optimization by shifting support cases to be serviced through other providers? And finally, tracking individual compliance through an HR-initiated workflow, where department level and individual level productivity can be monitored for driving business results.

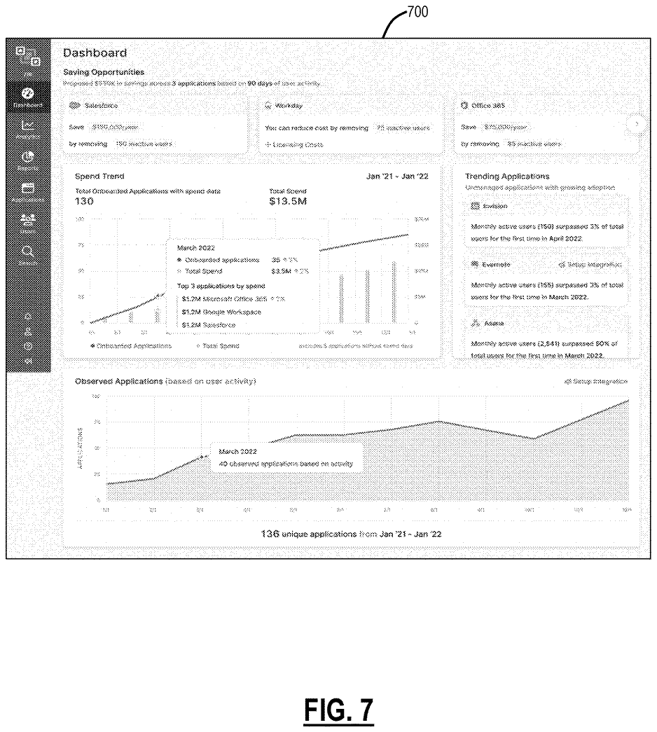

FIG. 7 is a screenshot of an exemplary business insights dashboard 700. The dashboard 700 provides various insights into applications, infrastructure, and an employee base associated with a cloud-based system and an organization. In the example shown in FIG. 7, the dashboard is displaying savings opportunities with various recommended actions which the organization can perform. More specifically, one of the features of the present systems and methods is to identify and display a number of inactive users associated with different applications/service providers, and a savings opportunity if those inactive users are removed. Additionally, the dashboard is adapted to display savings opportunities associated with individual applications and/or service providers in addition to a total savings opportunity, the total savings opportunity being the total financial savings if action is taken for each recommendation provided by the present systems and methods.

By collecting business insight data and providing application insights, enterprises/organizations can monitor application activity and trends. For example, if an enterprise is phasing out an application for a new one, the organization can monitor the migration process via the present insights. That is, if an organization is phasing out one SaaS vendor for another SaaS vendor, the organization can identify specific users and/or groups of users still using the old software and discover why those users have not yet migrated. It will be appreciated that the present example is one of many use cases for determining application migration across an organization via the present systems and methods, and other examples such as application migration, version migration, device migration, etc. are contemplated herein.

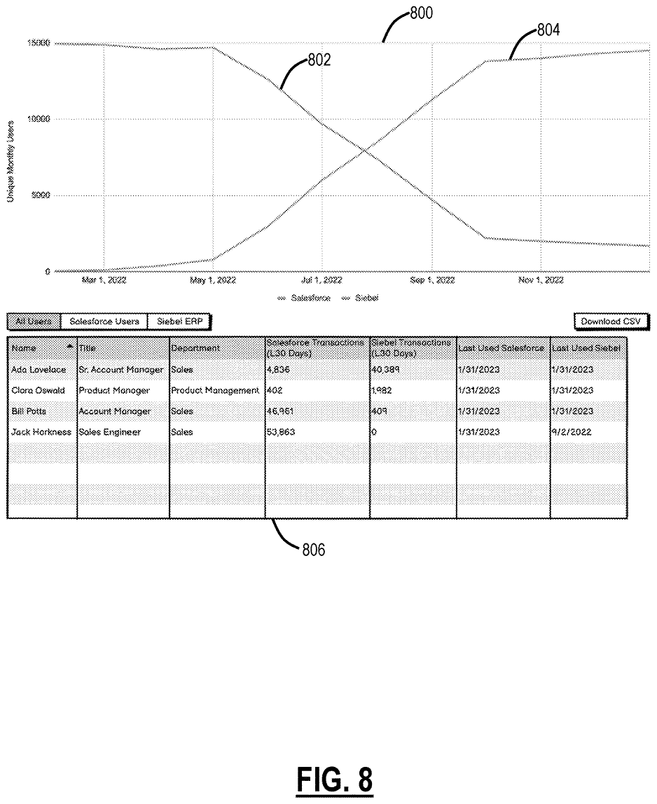

FIG. 8 is an example of application migration insights provided by the present systems and methods. Various embodiments are adapted to provide insights for application usage which is helpful when an organization is migrating from one application/service to another. A graphical representation of application usage is shown in the user migration graph 800. The user migration graph can show usage between a plurality of applications or services. In the example shown in FIG. 8, the user migration graph 800 shows usage between a phasing out application 802 and a phasing in application 804. Again, for example, if an organization is phasing out one vendor (application 802) for another vendor (application 804), the organization can identify specific users and/or groups of users still using the old software by utilizing the visual representation provided by the present systems and methods. Additionally, the visual representation can include a table 806 which can include statistics associated with specific users and the applications (802 and 804). The statistics can include, but are not limited to, a name of the users, title, department, number of transactions associated with the applications (802 and 804), date and time of last usage of the applications (802 and 804), and other insights of the like.

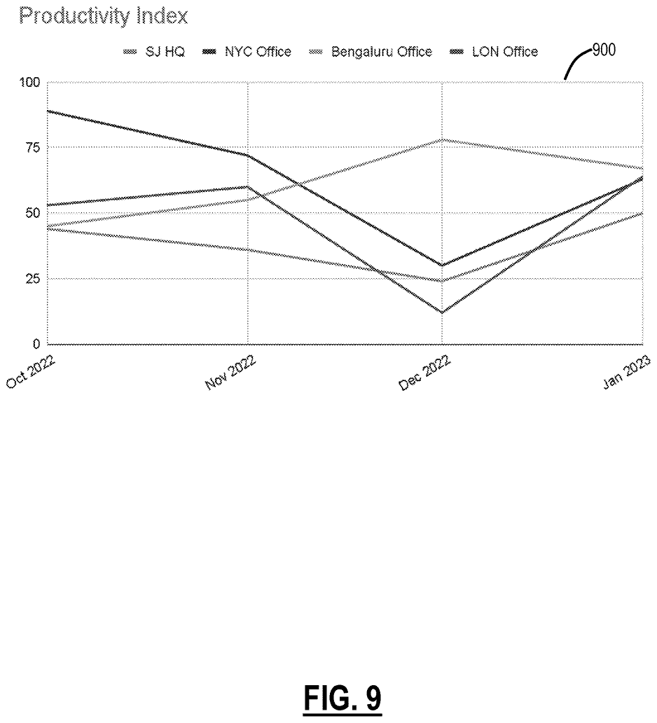

In various embodiments, the present systems and methods are further adapted to provide productivity insights. Such productivity insights can allow administrators to understand how different scenarios can affect productivity. For example, in an exemplary use case, a location productivity comparison can be provided by the present systems and methods. FIG. 9 is a graphical representation of productivity for a plurality of locations. A regional productivity graph 900 is shown, and visualizes productivity for a plurality of locations over a period of time. Such a visual representation can be used to understand how certain events, such as holidays, sporting events, etc., impact productivity in different locations.

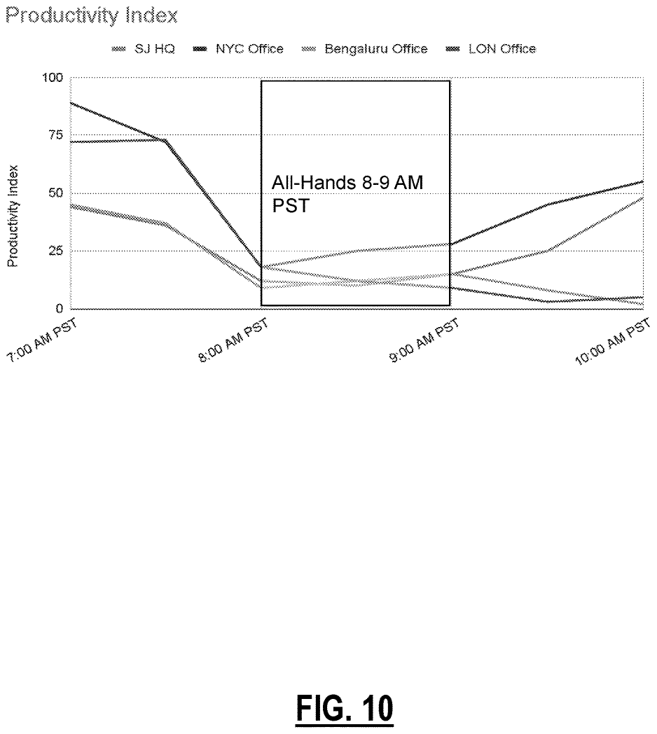

The time based productivity visualization, such as the one shown in FIG. 9, can also be used to determine how large meetings impact productivity across an organization. FIG. 10 is a graphical representation of productivity for a plurality of locations impacted by an organization-wide meeting.

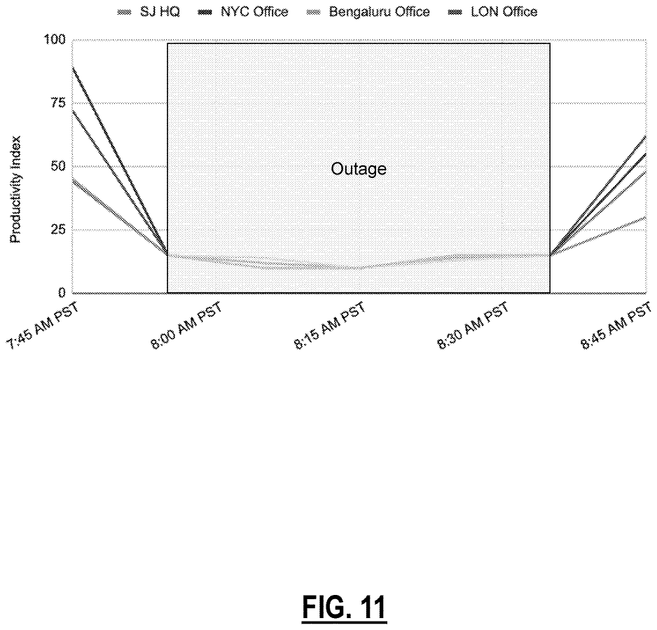

In another use case, the time based productivity insights can be used to understand how outages impact productivity. The user experience monitoring (ZDX) described herein can be used to detect outages of specific applications or services, and the present systems and methods can be used to collect productivity data and visualize how such an outage affects user productivity in various locations. FIG. 11 is a graphical representation of productivity for a plurality of locations impacted by an outage.

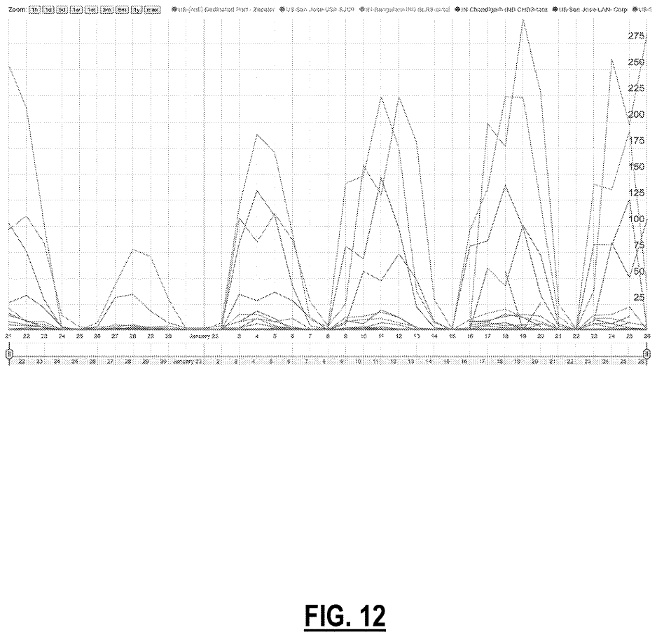

The present systems and methods are adapted to generate and provide various reports associated with the collected business insight data. In an embodiment, a report can be generated by the present systems to visualize the working habits of employees associated with an organization. For example, a report can be created to visualize office utilization. FIG. 12 is a graphical visualization of office utilization provided by the present systems and methods. The graph shown in FIG. 12 shows office utilization for a plurality of locations over a period of time. That is, the present systems are adapted to collect and process location data for employees of the organization in order to provide such visualizations.

In addition to the productivity insights disclosed herein, various infrastructure insights are also provided by the systems and methods. For example, the present systems and methods can be used to discover out of warranty devices, location specific bandwidth utilization, and other infrastructure insights of the like.

In an embodiment, the present systems and methods utilize application connectors for collecting business insight data. In addition to the application connectors, for applications that do not have connectors, data can be collected from an identity provider, such as Okta, and from the cloud services, including Zscaler Internet Access (ZIA), Zscaler Private Access (ZPA), and Zscaler Digital Experience (ZDX), all from Zscaler, Inc. (the assignee and applicant of the present application). This data (business insight data) can be utilized to provide the insights and to accommodate the various use cases described herein. For reviewing application engagement, the present systems and methods can provide engagement insight for a time period, including but not limited to the last 7 days, 30 days, 90 days, and 180 days, for determining engagement for highly used applications and applications that the organization uses less frequently. For rolling out an application, the present systems provide a breakdown of user engagement by active and inactive users to allow administrators to remove inactive users and reuse licenses. Additionally, when an administrator wants to review an application for compliance, the systems can provide a summary of the application's certifications and compliance issues.

The present systems are adapted to store at least 1 year of usage data for supporting comparisons and provide application statistics. When multiple sources of usage data are available, the present systems are adapted to utilize the data source with the highest confidence as default. The system is further adapted to discover applications being used by employees of an organization and recommend such discovered applications to be managed by the present systems. The system can show a filterable summary of all applications and a listing of all applications separated by applications that the organization has onboarded and applications that the system has discovered. Onboarded applications include applications which the organization wishes to receive insights for. The summary of onboarded applications includes total spend which is the sum of spend across all applications for which there is spend data, total applications which is the number of applications onboarded and currently being managed, and total discovered applications showing number of applications that can be added. In an embodiment, the system can send an administrator of the organization a discovered applications screen to add the discovered applications. A tabular listing of all onboarded applications can include the following columns.
Application
Purchased Seats
Provisioned Users
Active Users (over a period of time)
Engagement Index (over a period of time)
Last Month Spend
Risk Index
Sanctioned Status
Connection Status-Displays the status of the system's usage data retrieval, depending on the source of the usage data.

An administrator can filter through the applications using various filters including purchased seats, provisioned users, active users, risk index, sanctioned state, etc. The discovered applications screen shows a summary of all applications discovered by the systems. In an embodiment, once an application is onboarded, it will no longer appear in the discovered applications list. The tabular listing of all discovered applications includes the following columns.
Application Name
Provisioned Users
Active Users (over a period of time)
Engagement Index (over a period of time)
Risk Index
Sanctioned Status
Application Category

Clicking on any of the columns will sort the table by the clicked column. A search mechanism supports searching for an application by name. A user can filter applications using filters for provisioned users, active users, engagement index, risk index, sanctioned state, and data source.

The system can provide an application overview screen where users can investigate all aspects of an application. The overview screen is adapted to show the name of the application, the name given to the application by an administrator, a summary of total committed spend and total actual spend, the potential savings for the application in terms of the number of seats and dollars, and the like. For applications delivering data through a connector or an identity provider, the overview screen provides a description of the state of the connector or identity provider source. The system can also provide a path to remedy any issues with the data delivery, i.e., issues with the connector or identity provider. Further, for applications with a digital experience score, the system is adapted to display this score in the overview screen. Thus, the overview screen allows administrators to investigate engagement, plans, licensing insights, and application risk and compliance.

For application engagement, the system is adapted to display the activity observed for the application. The display can include the following. An engagement chart which includes a time series chart showing the number of active and inactive users for a given time period as a stacked area chart. If available, the chart can include the number of purchased seats and assigned seats as lines on the chart. A license usage summary includes billboard stats which describe purchased seats, assigned seats, active users, inactive users, etc. License usage details include a table showing all users assigned to the application. The data source for the table is based on the data source currently selected. The table columns include user (this can be the username or the full name, depending on the data available), total bytes, upload bytes, download, number of transactions, last active (this is the user's latest activity date based on connector information, or this is the user's last login date). The table can be filtered to show only active users or inactive users. The table columns are sortable. The user can export a CSV file that includes all columns in the table. The CSV export will be based on the filters, data source, and time period currently selected.

For application plans, the plans screen is adapted to display a table with plan information and let the user edit plan details such as plan cost, purchased seats (applications that don't have a connector won't have the number of purchased seats and the system will let the user add the number of purchased seats), provisioned seats (applications that don't have a connector or other integration won't have the number of provisioned seats and the system will let the user edit the number of provisioned seats).

For application licensing insights, the licensing insights page is adapted to display the license usage funnel with the previously described functionality. The funnel chart includes a total employees column. The system can infer the total number of employees either from the user CSV import or from the number of unique users observed in Single Sign On (SSO) integration. When the number of employees is inferred, the title of the column is “Estimated Total Employees”. The user can edit the “Estimated Total Employees” to define the actual number of employees. Once the user provides a number, the column changes to “Total Employees” and remains editable. The number of employees is a constant number that the system uses across all license usage charts.

For application risk and compliance, the risk and compliance section shows the application data from the SaaS security report. The system can display application information (headquarters, employees, year incorporated, application category, description, etc.), risk index (ZIA assigns a risk index to all applications and the system can use the ZIA risk index to describe the risk of an application), sanctioned status, and risk and compliance details.

When utilizing an identity provider (for example Okta) for providing application data, the system uses the provisioned count and application engagement metrics in the application overview summary counts and charts. For provisioned users, the system uses users provisioned to an application associated with the identity provider as the number for provisioned users. The system determines whether a user is active or inactive by using the date the user last authenticated to the application. Users can be added or removed from an application at any point. The system considers a user as assigned to an application if they were assigned to the application at any point during a period. For active users, the system determines that a user is actively using an application for the day when they authenticate through the identity provider for that application. For inactive users, the system can determine the number of inactive users for a period based by subtracting the number of active users from the number of provisioned users.

Each application discovery source will provide a user identity. To help the administrator understand who the users are, the user identity is mapped to a user profile that provides user-friendly information about the user, such as first name, last name, and department. A customer administrator can sync a full directory of their users to the system. The sync can be as simple as a CSV upload or support direct sync with a customer's active directory system.

The system is further adapted to provide an audit log of any configuration changes performed by a tenant's users. The log is searchable and accessible by customer administrators.

### Business Insights Architecture

In order for the present systems to collect the data required for providing the insights described herein, various scans are performed. These scans can include scanning onboarded applications via APIs, scanning IDPs, and the cloud services including Zscaler Internet Access (ZIA), Zscaler Private Access (ZPA), and Zscaler Digital Experience (ZDX). In various embodiments, a scan scheduler is responsible for initiating these scans for tenants of the cloud-based system 100. This scan scheduler can be communicatively coupled to a connector service which executes the scans on the various applications associated with the tenant.

These scans can include validation scans, catchup scans, and periodic scans. More particularly, validation scans are performed to verify if onboarded applications can be reached and if APIs can be invoked. Periodic scans are performed at preconfigured intervals for collecting the application data described herein. For example, these periodic scans can be triggered at midnight UTC and the like. Further, periodic scans for various tenants of the cloud-based system can be performed in a staggered approach to reduce load on the present business insight systems. Finally, catchup scans are performed to backfill missed days (up to a certain threshold), and when new applications are onboarded. After validation, these catchup scans can be triggered automatically if the periodic scan is lagging. As stated, the connector service is adapted to execute scans on applications based on triggers from the scan scheduler.

In various embodiments, validation scans are performed via the following procedure. The scheduler is configured to find all new added applications based on a preconfigured time interval. That is, the scheduler is configured to, every minute (or other time span), scan/poll for newly added applications. When new applications are detected, the scheduler causes the connector service to perform a one-time immediate scan and return the scan status and data to the scheduler. Once this is performed, the application is marked as validated, and the scheduler can add this application to its periodic scanning.

In various embodiments, catchup scans are performed via the following procedure. Once an application has been validated, i.e., once the validation scan has been completed, the scheduler is adapted to cause the connector service to perform a catchup scan for a preconfigured amount of historic time. For example, the catchup scan can scan the last 7 days to collect insight data. This process for newly onboarded applications is performed because no data will be available to display for the newly onboarded application, thus the catchup scan allows the systems to collect data from a predetermined previous time span for displaying via the various UIs (dashboard and associated screens) described herein.

In various embodiments, the scheduler causes the connector service to perform the various scans via Representational State Transfer (REST) API calls, and the connector service is adapted to return any scan results to the scheduler based thereon. From there, the scheduler can communicate the results, which include the business insight data described herein, for being displayed via the various UIs such as the dashboard shown in FIG. 7. Again, this business insight data can include engagement, plans, licensing, etc. for each of the tenants' applications, as well as location information further described herein.

In various embodiments, periodic scans are performed via the following procedure. Based on a preconfigured time interval, for example every 24 hours, the scheduler will cause the connector service to perform a scan of all validated applications. These periodic scans can be scheduled for specific times of the day either based on UTC or local time of each tenant of the cloud-based system.

In various embodiments, responsive to a preconfigured number of failed scans, the systems can notify an administrator of the tenant and request a re-onboarding of the application in order to initiate a new validation scan.

It will be appreciated that the components described herein such as the scheduler, connector service, and the like can be executed on various components of the cloud-based system 100. That is, the operations of the scheduler, connector service, etc. can be performed via any of the nodes 150, servers, virtual machines, etc. associated with the cloud-based system.

The business insight system described herein can be adapted to receive signals and data from various sources including the ZIA service, which acts as one of the input feeders; identity providers (IDPs) such as Okta and Entra ID, etc.; and direct SaaS app connector integrations with platforms such as Okta, M365, Salesforce, ServiceNow, Slack, Box, Google Workspace, GitHub, and the like. The present systems provide metrics even if integration with a specific app is unavailable, leveraging data from other sources.

The present systems differentiate between subscribed apps and used apps by populating metadata fields with subscription details, including cost, license plans, contract start dates, end dates, etc. These fields can be filtered to generate reports on representative apps. Simultaneously, the present systems presents app usage and workplace data by analyzing inline traffic, identity provider login data, and API integrations with direct app connectors. This comprehensive analysis helps organizations save on business costs.

The present systems allow tenants to experience total visibility into their SaaS application landscape with a complete inventory that lists all SaaS applications in one place, including redundant ones, ensuring a clear understanding of app usage and inventory. Because of this, administrators can effortlessly monitor app engagement through a detailed user and engagement index that provides insights into their plans and seats purchased, as well as active user metrics and top usage by department. This helps tenants manage and optimize app utilization effectively. The cost matrix feature helps tenants reduce SaaS sprawl and unnecessary spending by comparing app usage with costs, identifying opportunities for consolidation and cost reduction. The systems further allow tenants to leverage data over any duration such as days, weeks, months, or quarters to effectively execute their return-to-office strategy. This long-term visibility supports better planning and adaptation to changing work environments. Finally, tenants can save time and effort on data consolidation, providing a clearer, more accurate picture of the organization's software and workplace dynamics, enabling better decision-making and resource allocation.

### Business Insights Process

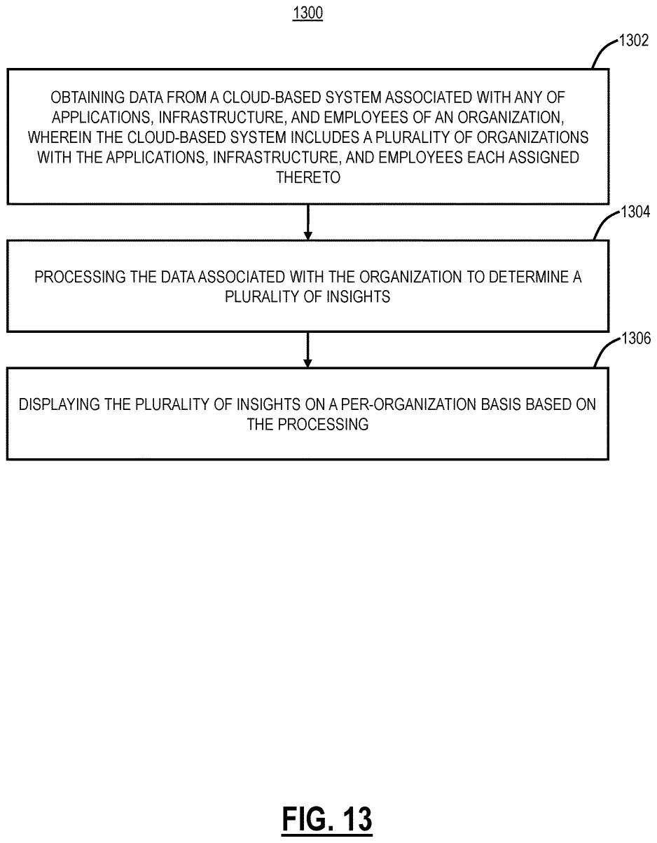

FIG. 13 is a flowchart of a process 1300 for collecting and providing business insights for an organization. The process 1300 includes obtaining data from a cloud-based system associated with any of applications, infrastructure, and employees of an organization, wherein the cloud-based system includes a plurality of organizations with the applications, infrastructure, and employees each assigned thereto (step 1302); processing the data associated with the organization to determine a plurality of insights (step 1304); and displaying the plurality of insights on a per-organization basis based on the processing (step 1306).

The process 1300 can further include wherein the data includes usage data associated with one or more applications of the organization. The displaying can include providing a graphical representation of application usage associated with the one or more applications of the organization. The usage data can include application license data, wherein the application license data includes a number of active and inactive users associated with the one or more applications of the organization. The steps can further include displaying a savings opportunity associated with the one or more applications of the organization based on the application license data. The savings opportunity can be associated with a specific application, or all applications associated with the organization. The data can include certification and compliance data associated with one or more applications of the organization. The data can include productivity data associated with the employees of the organization, wherein the displaying includes providing a graphical representation of productivity for different locations associated with the organization. The data can include location data associated with the employees of the organization, wherein the displaying includes providing a graphical representation of office utilization for the organization. The data can be obtained from any of an application connector and an identity provider associated with the one or more applications.

### Inferred Locations

It is common for organizations to forget to configure their locations in a cloud providers portal. Due to this, it is difficult for an organization to know whether their employees are working from which office locations as every user will be seen as a remote worker even if he/she is working from office premises. The present disclosure provides systems for automatically detecting organizations' office locations based on their data, such as the business insight data described herein. Two parts to this problem include detecting office IPs which might be an organization's location public IP and detecting exact geo coordinates for those detected office locations.

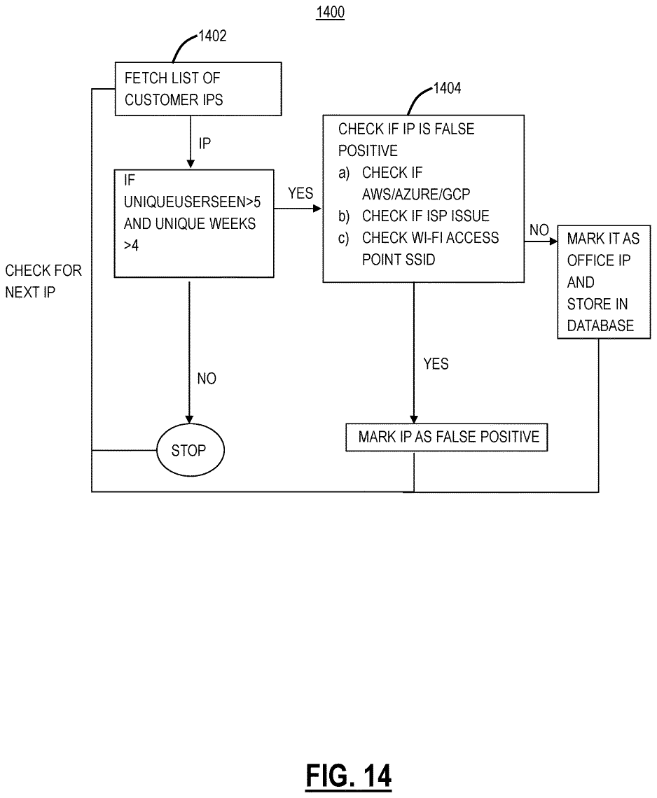

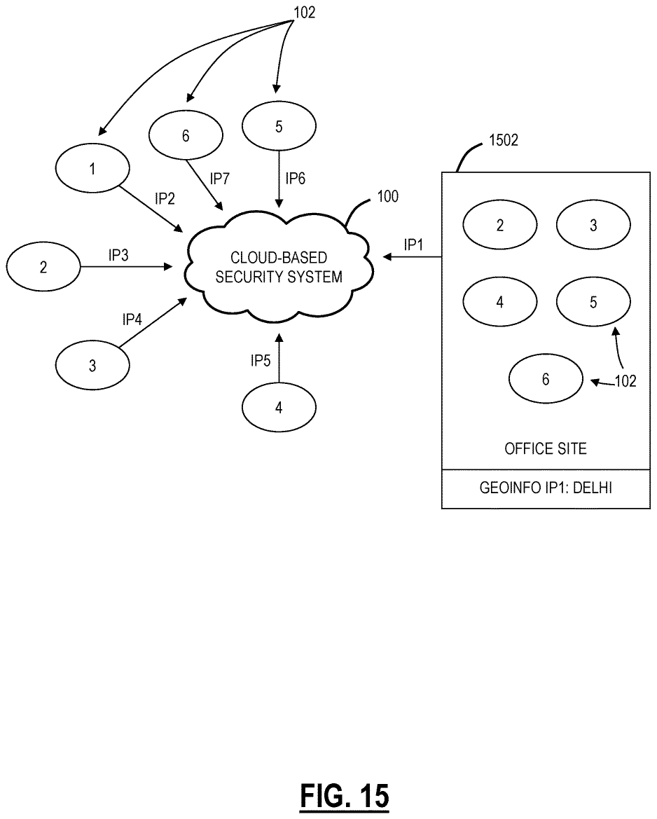

FIG. 14 is a flow diagram of a process 1400 for detecting office IPs (IP addresses). Using an organization's log data available to the cloud-based system 100, systems are adapted to perform an analysis of all the IPs which are seen as remote IPs for a period. That is, the process includes fetching a list of IPs associated with traffic of an organization (step 1402). If any IP in the list is not associated with any known location (known office location of the organization), and If the system sees more than 5/10 (or any other fraction) of users in a day from the IP, and this is a pattern for the IP for a period, then it will be marked as contender for an organization office IP. This is performed to eliminate false positives associated with customer events. For example, a customer may hold an event at a location, thus, many employees will be seen at that location for the span of the event. The user patterns are thus analyzed over a period of time.

Once a list of contender IPs is derived, the system can perform various analyses/techniques for mitigating false positives (step 1404) to filter the list. Whatever contender IPs the system finds, it checks if those are owned by any public cloud, if yes, the system removes those IPs from the contender list. This could be a workload running in the public cloud or could be a virtual desktop hosted in the cloud. The same situation could arise if a customer is running their Data Center (DC) in which case, it would be expected that the customer would share IPs attached to their DC and thus can be used to filter out contender IPs. Further, there are rare cases where an Internet Service Provider (ISP) will use the same egress IP for multiple users that might not be in the same geographic region/vicinity. Using the digital experience monitoring data described herein, where there are complete My Traceroutes (MTR's) for those IPs, or other path trace data, the system can detect whether the IP usage is related to an ISP issue. For example, if the system detects a threshold number of private IPs in MTR hops, then the system can assume it is due to an ISP geo networking issue. Further, using the digital experience data, to get more confidence for contender IPs, the system checks that all users going through the IP have similar Wi-Fi access point names, if 70-75% of users have similar Wi-Fi access point names, the system gives a higher confidence score to the IP, meaning that it is more likely to be an office IP and not considered a false positive. It will be appreciated that any other percentage of users is contemplated for determining confidence scores.

There are cases where organizations have many IPs of similar subnet for offices. Instead of showing the organization all individual IPs as individual potential offices, the system clusters IPs based on if a geo distance between the IPs is less than x miles, meaning it might be the same office building. Based on this, the system can tag many IPs together to one inferred potential office location.

Based on the findings from process 1400, the present systems can present a list of potential office locations of the organization within the various UIs described herein.

In various embodiments, in order to increase the confidence of the inferred office locations the following steps are contemplated. If both the database and IP information are showing the same location, and the system has not seen their coordinates changing in the last 1-2 months (or other period), the system can give a high confidence score to this IP geolocation. If both are showing geolocations less than 10 miles apart, the system can still give them high scores and see if their postal code is the same. If the distance between geolocations provided by the database and IP information is more than 10 miles (or other distance), the system will perform a tie breaker by using the below analysis.

For IPs which the system is seeing different geolocations, it will do following. For each inferred office IP, collect samples of users going through that IP. For each user, find all other IPs (i.e., home IP, phone IP, etc.). Find an IP other than the inferred office IP for which the user is seen on for a maximum of days and collect its geolocation. Find maximum geolocation repetition based on all of the users. Check if this geolocation is near to geolocation suggested by the database and IP information. If it is under 25-50 miles (or other distance threshold) to any of the geo coordinates, then that geolocation is assigned a high confidence. Alternatively, a low confidence score is given to that geolocation.

Based on the user location triangulation, the system can now tell if the user is using a Virtual Private Network (VPN) or not. If the system sees that the sample user location (using home IPs) is 100's of miles from the inferred office IP location, the system can give good confidence to the user traffic and IP that this might be an office IP.

### Improved Site Geo-Accuracy Based on User IPs

Using IP to Geo lookup databases, such as those provided by MaxMind, is a common practice to determine the geographic location of a user or entity based on their IP address. These databases leverage various data sources to map IP addresses to physical locations, offering valuable insights for businesses, security professionals, and researchers. However, the accuracy of these services is not 100% guaranteed. Several factors contribute to potential inaccuracies. The accuracy of geographic location data depends on the quality and recency of the sources from which the database compiles its information, such as regional internet registries, internet service providers, and third-party data. Additionally, many internet service providers use dynamic IP addressing, meaning that IP addresses can be reassigned to different users and locations over time, leading to discrepancies between the actual location of an IP address and the location recorded in the database. Users also often employ proxies, virtual private networks (VPNs), and other anonymizing services that can mask their true geographic location, making it difficult for IP to Geo lookup databases to provide accurate information.

Furthermore, different versions of the same IP to Geo lookup service can produce varying results because each version may be updated with new data or corrections at different times. Consequently, the same IP address might resolve to multiple geographic locations depending on which version of the database is being used. The granularity of the geographic information can also significantly impact the usefulness and precision of the location data. While some IP to Geo lookup databases can provide city-level accuracy, others may only offer country-level or regional data. Additionally, the policies and practices of IP address allocation by internet service providers and regional registries can influence the accuracy of geographic location data. For instance, IP blocks may be allocated to large corporations or institutions with multiple geographic locations, complicating the resolution process.

In an example, suppose an organization/customer of the cloud-based system 100 configures a location X having a total number of employees N via the UI described herein. That is, the present systems can allow customers to configure such locations via the portal/UIs described herein for business insight data ingestion and display. This can be done by binding IPs for that office location. Initially, based on IP lookup, the specific office location may be identified as being in Delhi India. Over a period of time, the geo lookup can be stable, i.e., resolving the IP to Delhi or it could change to a different city such as Mohali, India. To solve this, the present systems and methods introduce a user geo triangulation process to confirm the exact geolocation of an office site of the organization.

The log data available to the cloud-based system 100, in addition to the business insight data described herein, has users egress IP information irrespective of whether they are connecting from an office site or they are connecting from another location such as their home. Based thereon, the present process can find out and identify all users going through an office site IP. FIG. 15 is a diagram of various users 102 accessing the cloud-based system 100 via various IPs including home IPs and office site IPs. In FIG. 15, users 2, 3, 4, 5, and 6 are connecting through IP1 of the office site 1502 in addition to their home IPs. As can be seen, the geo info from IP lookup shows a location of Delhi for IP1. Based thereon, the process includes determining which users are connecting through the office site 1502 IP. After determining which users are connecting through the office site 1502 IP, the process includes, for those identified users, determining an egress IP when they are connecting from their homes. Based on the available data to the cloud-based system 100, the IPs of the users 102 when they are working from home and their associated geolocations are as follows:
User 1, IP2, Mohali
User 2, IP3, Mohali
User 3, IP4, Mohali
User 4, IP5, Chandigarh
User 5, IP6, Mohali
User 6, IP7, Ludhiana

Based on this information, if the system clusters users 102 based on geolocation, it clearly shows that most of the users 102 connecting from the office site 1502 are also working from their home from Mohali which is approximately 150-200 miles from Delhi. Thus, the geolocation of the site should be in or around Mohali and not Delhi, as it is impossible for users to travel such a distance for commuting.

In other terms, the present process includes first determining a group of users that access the cloud-based system 100 from an office site 1502. After identifying the group of users that utilize the office site 1502, the process includes determining each of those user's home egress IPs and associated geolocations when they are working from home. These home locations can then be used to cluster the users and determine where a majority of the users geolocations are when they are working from home, this is referred to as a majority location. Based on the identified majority location, the location of the office site 1502 can be altered based on a distance threshold. That is, if the majority of the users that utilize that office site 1502 also work from home in a majority location that is above a preconfigured threshold distance to the current office site 1502 location, the office site 1502 location can be changed to the majority location. For example, if a group of users use a specific office site 1502, but the majority location of those users is above 50 miles, or other threshold, from the current office site location, the present systems can provide a recommendation that the office site location should be changed to the majority location via the UI.

This process can also be utilized to confirm the accuracy of an office site's geolocation in the portal. That is, if the current geolocation of the office site 1502 turns out to be the same location as the user's majority location, then the system has confirmed that the geolocation of the office site 1502 is correctly labeled in the portal/UI. Based on such findings, confirmation/verified labels can be displayed next to office site locations in the UI to show users that these locations have been vetted and confirmed with high confidence.

### Inferring Location Labels Based on Popular Cities

Typically, information within geo databases include entries of city, region (state), country, latitude, and longitude location information. In most cases, within the city entry, the name of a suburb is provided which causes the location determination to become difficult due to customers needing to infer what the suburb is. Based on this issue, the present processes include steps for determining a closest major city to a suburb, making it easier for customers to recognize the location.

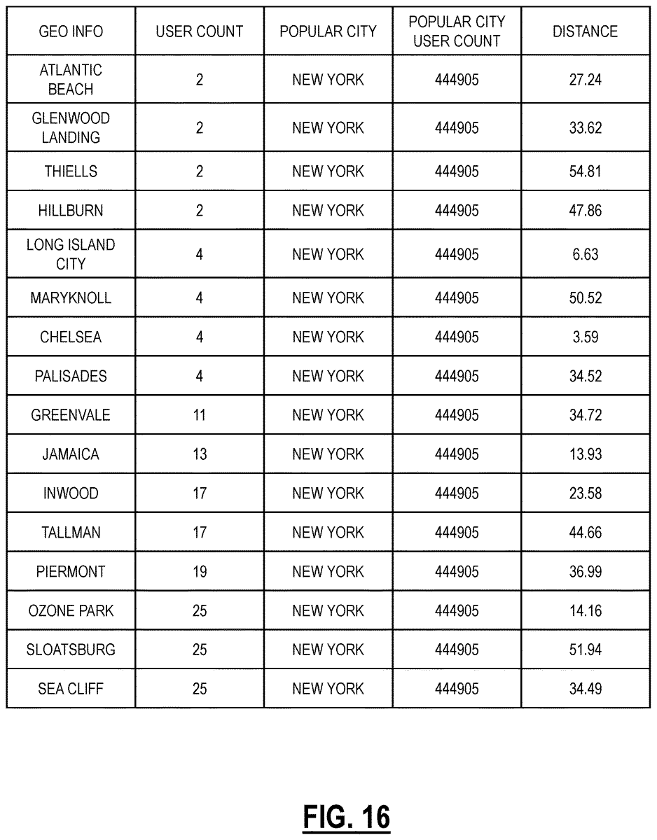

Because the present systems have access to user browsing information via the cloud-based system 100, a distribution of users across different cities can be computed. By utilizing the density of users as a metric, the present processes can rank popular cities. In various embodiments, based on such distributions, cities that hold more than a threshold number of users can be considered popular cities. The process can then include iterating through the rest of the cities that hold users and determine popular/metro cities, and find out the closest city that passes the threshold for being a popular city. FIG. 16 is an example of an organization's user location data. In the example shown in FIG. 16, the analysis shows that New York is the closest popular city for all nearby suburbs. Again, the determination of a “popular city” is based on the number of users within that city in the geo data. Further, for tenant/organization-based analysis, the identification of a popular city can be based on a percentage of the organizations users that are located in a specific city. Data, such as the data shown in FIG. 16, can be used to determine popular cities for customers of the cloud-based system based on their associated data sets. The data in the user location data can include geo info (geo location of a set of users), user count (within that geo location), associated popular city, popular city user count, and distance between the geo location and the popular city.

By leveraging this data, the present systems can make various recommendations and determinations such as an opportunity to open a new office location for the organization. That is, in one use case, the present systems can provide recommendations to open one or more office locations based on user distribution. For example, if the distribution includes a large number of users in a geo location that is more then a threshold distance form the closest popular city, the systems can recommend to open an office location for the geo location.

In various embodiments, this process can be utilized to determine if users who live near an office site are actually utilizing the office site. Further, the findings from the present analysis can be leveraged to determine if it would be beneficial for a customer/organization to open a new office site or data center in a new location. For example, an organization may have a data center or office site in Delhi, but if the system determines that a popular city such as Chandigarh also has an equivalent, or relatively large number of users, then it might be an option for the organization to open or setup a new site near the Chandigarh area. Based on such findings, the present systems can provide a detailed recommendation to show the organization that it may be beneficial to open a new site for its employees.

### Office Location Differentiation

Typically, methods depend on geo IP lookups to determine if an IP belongs to the same city, where based on geo distance, proximity of IPs can be determined. A problem with these methods includes that if the geo lookup provides a wrong geo location for any IP, the analysis will be rendered incorrect and lead to incorrect mappings of IPs to a same organization building. This can be solved by taking manual inputs from customers for each of their IP to building mappings, although this is cumbersome and time consuming for the customer. Based on this, the present processes include a user overlap analysis to predict whether IPs belong to the same office site or not.

Again, because the cloud-based system 100 has access to egress IP data associated with offices from where users are working, the present systems can map those IPs to specific locations. However, organizations can use a plurality of IPs for their egress traffic from the same office site. In such cases, it can be difficult to determine if those IPs are associated with one office site having a plurality of egress IPs, or a plurality of office sites. Based thereon, the systems can perform an analysis to determine if there are users who's traffic egresses through multiple IPs. If so, the systems can conclude that those IPs belong to the same office site, as it is unlikely that a user moves between a plurality of office sites on a daily basis.

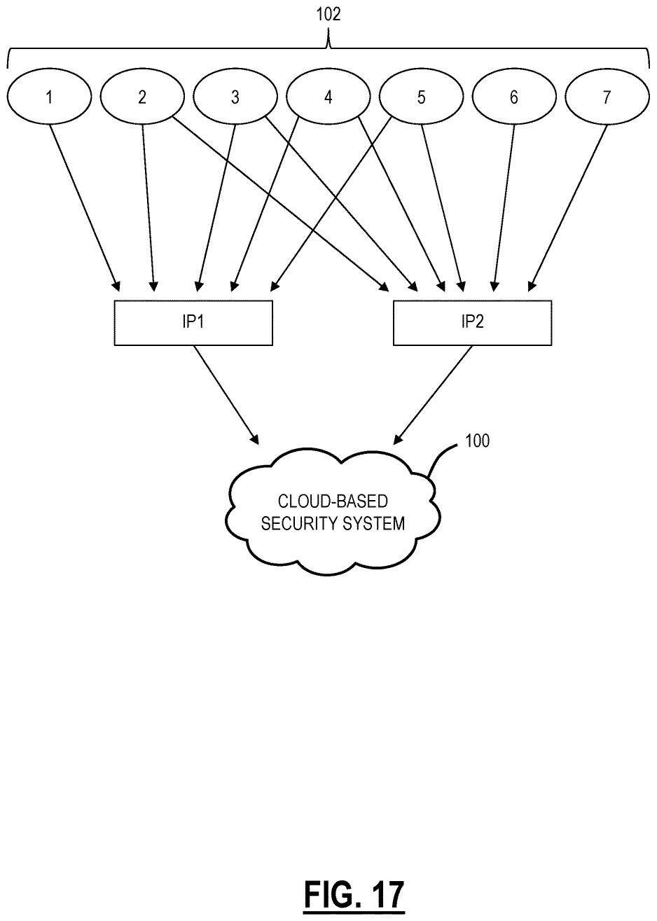

FIG. 17 is a flow diagram of a plurality of users 102 utilizing a plurality of IPs for connecting to the cloud-based system 100. In the example shown in FIG. 17, it can be seen that users 2, 3, 4, and 5 are connecting to the cloud-based system 100 through the same two IPs over a period of time. Based on this, the systems can conclude that the two IPs belong to the same office site. More particularly, the determination can be made based on a percentage of users that utilize the two IPs out of the total users associated with each of the IPs. That is, if out of the total number of users associated with the two IPs, a percentage of the users that do utilize both IPs is above a threshold, the systems can assign both of the IPs to the same office site. It will be appreciated that this analysis can be performed for any number of users and any number of IPs for determining IPs that belong to specific office sites. That is, the present processes can be utilized to determine groups of IP addresses of an organization that belong to a specific office site location of the organization.

This process enhances the business insight experience for organizations by improving the accuracy of metrics. This is because organization office site locations can be better labeled and tracked, allowing organizations to better understand their attendance, occupancy, and other metrics related to office usage. For example, by determining that a plurality of IPs are associated with a single office site, the present systems can provide better attendance metrics and the like. This also improves the efficiency of IT teams as they don't need to manually check for all the IPs to see if it is a same office site or not. That is, the present processes can be performed by the cloud-based system automatically to combine individual organization IPs into one or more office sites.

### Process for Office Site Location Determination and Verification

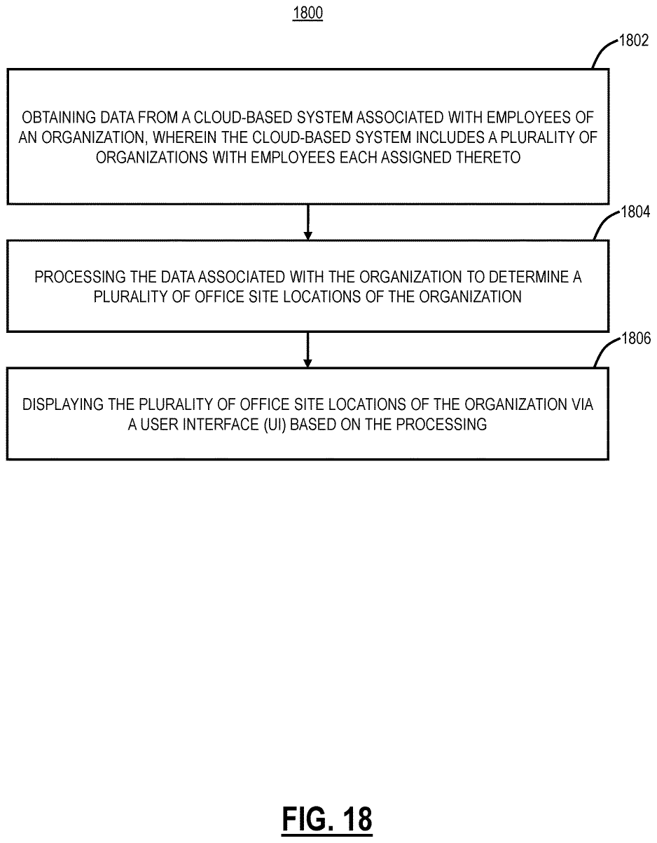

FIG. 18 is a flowchart of a process 1800 for office site location determination and verification. The process 1800 includes implementation as a method with steps, a cloud-based system configured to implement the steps, and a non-transitory computer-readable medium storing computer-executable instructions for causing performance of the steps. The steps include obtaining data from a cloud-based system associated with employees of an organization, wherein the cloud-based system includes a plurality of organizations with employees each assigned thereto (step 1802); processing the data associated with the organization to determine a plurality of office site locations of the organization (step 1804); and displaying the plurality of office site locations of the organization via a User Interface (UI) based on the processing (step 1806).

The process 1800 can further include generating a list of contender Internet Protocol (IP) addresses based on the data, wherein the list of contender IP addresses includes one or more IP addresses each associated with a location; performing one or more false positive mitigation techniques for filtering the list of contender IP addresses; and determining one or more office site locations of the organization based thereon. The one or more false positive mitigation techniques can include any of (i) determining if an IP address is owned by a public cloud, (ii) determining if the use of the IP address is associated with an ISP issue, and (iii) determining if users utilizing the IP address have similar access point names. The steps can further include generating a list of potential office site locations based on the determining. The steps can further include retrieving a list of office site locations of the organization, the list including a plurality of geo locations representing office site locations of the organization; processing the data associated with the organization to determine an accuracy of each of the geo locations in the list of office site locations. The steps can further include labeling each of the office site locations in the list based on the determining, wherein a label represents a confidence in the accuracy of each of the office site locations in the list. The processing can include utilizing an office site Internet Protocol (IP) address and a plurality of user home IP addresses to determine an accuracy of a geo location of an office site. The steps can further include providing a recommendation to update a geo location of an office site in the list based on determining the geo location of the office site is incorrect, wherein a correct geo location of the office site is determined based on the plurality of user home IP addresses. The steps can further include providing one or more office site recommendations for the organization based on the processing. The steps can further include processing the data associated with the organization to determine one or more groups of Internet Protocol (IP) addresses that belong to a same office site location of the organization.

It will be appreciated that all of the present methods for determining, recommending, and verifying organization office site locations can be performed in combination to provide organizations with detailed views, via the UIs described herein, of their office site distribution along with metrics such as attendance.

### Intelligent Floor-Level Workplace Occupancy and Utilization

The present invention provides an intelligent spatial analytics system that transforms digital experience monitoring telemetry into granular, near-real-time, and predictive insights regarding workspace utilization, without requiring additional physical sensors or hardware. The core technology, referred to herein as the intelligent spatial analytics engine, addresses the long-standing enterprise problem of understanding how corporate real estate is actually used. Although organizations invest billions of dollars in office space, they lack accurate, data-driven mechanisms to answer fundamental utilization questions such as how many people were present on a given floor at a specific time, which floors are underutilized and candidates for consolidation, or what the current estimated occupancy is during an emergency. Traditional approaches, such as deterministic mapping of a single connected Wi-Fi access point (BSSID) to a floor, are brittle and unreliable due to signal overlap between floors, outdated configurations, roaming devices, and noisy telemetry. Moreover, installing physical occupancy sensors is expensive, operationally complex at global scale, and may introduce employee privacy concerns.

To overcome these limitations, the invention introduces a novel intelligent processing layer that operates between existing data ingestion pipelines and downstream analytics systems. Rather than replacing current infrastructure, the system enhances it by transforming ambiguous Wi-Fi telemetry into clean, stable, and predictive floor-level occupancy insights. The architecture includes three principal stages: (1) a data ingestion layer that receives Wi-Fi change events, including events originating from tables upon changes in device Wi-Fi connections, (2) the intelligent spatial analytics engine, and (3) a data serving layer that exposes both real-time and historical analytics. The data flow is event-driven and processes information as it arrives, enabling near-real-time updates of floor occupancy.

At the heart of the system is the Probabilistic Spatial Inference Engine (PSIE), which constitutes the first layer of intelligence. The PSIE resolves device location from ambiguity to probability for each incoming Wi-Fi change event. For every device event, the PSIE receives an enriched record containing: (i) a temporary device identifier (device_id), (ii) a timestamp, (iii) a list of all visible Wi-Fi access points (visible_aps) along with their signal quality percentages (0-100), and (iv) an office configuration mapping (office_config) that associates known BSSIDs with their physical floors. Unlike conventional systems that rely solely on the currently connected access point, the PSIE evaluates all visible Wi-Fi signals to compute the most probable floor location.

To achieve this, the PSIE applies a non-linear signal weighting function to convert signal quality percentages into exponentially weighted values. In one embodiment, the signal quality value is squared (e.g., 90% becomes 902=8100), thereby giving disproportionately greater importance to stronger signals and ensuring that a single strong signal can outweigh multiple weaker signals (e.g., two 60% signals totaling 7200). Using these weights, the PSIE executes a floor scoring procedure: for each visible BSSID, it identifies the associated floor via the office_config mapping, converts the signal quality to a weight, and aggregates weights per floor. The floor with the highest total score is selected as the inferred floor. A confidence score is then computed by dividing the winning floor's score by the sum of all floor scores. The PSIE outputs an enriched object containing the device_id, timestamp, inferred_floor, and confidence value.

The enriched inference is passed to the Temporal State Management (TSM) module, which provides stability and noise rejection in the event-driven stream. Because Wi-Fi signals can fluctuate and devices may briefly appear ambiguous (for example, in stairwells or transitional areas), the TSM acts as the final arbiter of a device's location. The TSM maintains per-device state information in a low-latency cache, such as Redis, including the current_stable_floor and the last_stable_timestamp. The TSM applies a confidence-gated state change mechanism. If the PSIE confidence score is below a predefined threshold (e.g., 0.75), the event is discarded as noise and no state change occurs. If the confidence exceeds the threshold, the TSM compares the inferred floor with the current stable floor. If the inferred floor differs, the TSM confirms a location change, updates the device's stable state with the new floor and timestamp, and emits a LOCATION_CHANGE event downstream. If the inferred floor is the same, the timestamp is updated but no change event is emitted. This selective emission mechanism ensures that only validated, high-confidence movements affect occupancy counts in both historical datastores (e.g., Azure Data Explorer (ADX)) and real-time state stores.

The system further incorporates an asynchronous Machine Learning (ML) module that provides adaptive and predictive capabilities. In its adaptive learning function, the module performs self-healing configuration management by analyzing high-confidence inferences from the TSM. When an unknown or unmapped BSSID repeatedly appears in visible_aps lists for devices confidently located on a particular floor, the module infers that the unknown BSSID likely belongs to that floor. After accumulating sufficient evidence, it can flag the mapping for administrative approval or automatically update the office_config table, thereby reducing manual configuration overhead and improving long-term accuracy. In its predictive analytics function, the module leverages historical aggregated data to train time-series forecasting models, such as ARIMA or Prophet, that learn daily, weekly, and seasonal occupancy patterns. These models generate forward-looking occupancy forecasts (e.g., predicted occupancy for a floor on a future date) and also produce “now-casts” that intelligently estimate current occupancy levels to bridge inherent telemetry delays (e.g., a 20-30 minute reporting lag).

The data serving layer exposes multiple data products, including an aggregated analytics datastore for business intelligence and trend analysis, a near-real-time state store for live dashboards, and a prediction datastore for forecasted occupancy. Through this architecture, the invention delivers concrete, floor-level occupancy counts in near real time, enabling data-driven decisions regarding office layout optimization, real estate consolidation, and emergency response planning. The system is designed with privacy at its core: it operates on temporary device identifiers and produces aggregated floor-level counts rather than tracking individuals. Additionally, because it leverages existing telemetry and Wi-Fi infrastructure, it avoids the significant capital and operational expenditures associated with deploying physical occupancy sensors and scales seamlessly across global office environments without requiring local hardware installation.

In sum, the invention provides a scalable, privacy-centric, hardware-free, and probabilistically robust system for intelligent floor-level workplace occupancy and utilization detection by combining probabilistic modeling, confidence-gated temporal state management, and adaptive and predictive machine learning within an event-driven architecture layered atop existing experience monitoring telemetry infrastructure.

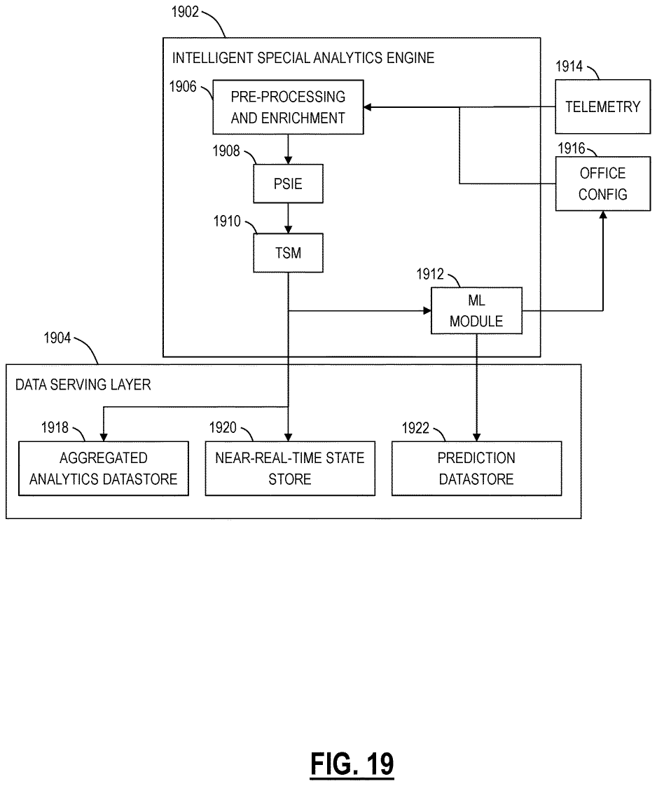

FIG. 19 illustrates a high-level architectural of a system for intelligent floor-level workplace occupancy and utilization detection. As shown, the system includes an intelligent spatial analytics engine 1902 and a data serving layer 1904. The intelligent spatial analytics engine 1902 represents the core processing component and includes multiple functional modules arranged in a processing sequence.

Within the intelligent spatial analytics engine 1902, a pre-processing and enrichment module 1906 receives input data and prepares enriched event records for downstream analysis. The pre-processing and enrichment module 1906 is communicatively coupled to external data sources, including telemetry 1914 and office configuration data 1916. The telemetry component 1914 provides Wi-Fi-related device telemetry events, while the office configuration component 1916 provides configuration data that maps network identifiers (e.g., BSSIDs) to physical floor locations. The pre-processing and enrichment module 1906 uses these inputs to construct enriched data structures suitable for probabilistic analysis.

Output from the pre-processing and enrichment module 1906 is provided to a Probabilistic Spatial Inference Engine (PSIE) 1908. The PSIE 1908 performs probabilistic floor inference based on the enriched telemetry data and configuration mappings. The PSIE 1908 generates inferred floor determinations along with associated confidence values.

The inferred outputs from the PSIE 1908 are provided to a Temporal State Management (TSM) module 1910. The TSM module 1910 maintains state information for devices and validates inferred location changes over time, thereby filtering transient or low-confidence events and producing stable location determinations.

The TSM module 1910 is further communicatively coupled to a Machine Learning (ML) module 1912. The ML module 1912 operates in conjunction with the outputs of the TSM module 1910 to perform adaptive learning and predictive analytics. In addition, the ML module 1912 is communicatively coupled back to the office configuration component 1916, enabling feedback-based updates to configuration data, such as inferred mappings of previously unknown access points.

The data serving layer 1904 receives processed outputs from the intelligent spatial analytics engine 1902. In the illustrated embodiment, the data serving layer 1904 includes an aggregated analytics datastore 1918, a near-real-time state store 1920, and a prediction datastore 1922. The aggregated analytics datastore 1918 stores historical and trend-based occupancy data. The near-real-time state store 1920 maintains current occupancy and device state information suitable for live dashboards and operational visibility. The prediction datastore 1922 stores forecasted occupancy data generated by the ML module 1912.

In an example workflow, a device carried by a user transitions from a first floor to a second floor within an office. The process begins when telemetry 1914 reflects a Wi-Fi change event, such as a new connected BSSID and an updated list of visible access points. This event is transmitted to the intelligent spatial analytics engine 1902, and more specifically to the pre-processing and enrichment module 1906.

Upon receipt of the telemetry event, the pre-processing and enrichment module 1906 queries the office configuration datastore 1916 to obtain mappings between BSSIDs and physical floors for the relevant office. The office configuration component 1916 returns the configuration data, which the pre-processing and enrichment module 1906 uses to enrich the telemetry event. The enriched event includes, for example, a device identifier, timestamp, visible access points with signal quality values, and associated floor mappings. The enriched device event is then forwarded to the PSIE 1908.

The PSIE 1908 performs probabilistic floor determination. Using the signal quality values and the floor mappings from office configuration 1916, the PSIE 1908 calculates weighted scores for each candidate floor and determines an inferred floor along with a confidence score. For example, the PSIE 1908 may determine that the device is most likely located on Floor 3 with a confidence of 0.87. The inferred_floor and confidence are then provided to the TSM module 1910.

The TSM module 1910 retrieves the device's current stable floor from its maintained state. Assume that the current_stable_floor is Floor 2. The TSM module 1910 applies a confidence threshold test. If the confidence exceeds a predefined threshold and the inferred_floor differs from the current_stable_floor, a confirmed location change is determined. In this example, because the confidence is high and the inferred floor (Floor 3) differs from the stored floor (Floor 2), the TSM module 1910 updates the device's stable state to Floor 3 and records the updated timestamp.

Following confirmation of the location change, the TSM module 1910 propagates updates to the data serving layer 1904. The updated occupancy state is written to the near-real-time state store 1920 to reflect current occupancy counts, such as decrementing the count for Floor 2 and incrementing the count for Floor 3. In parallel, historical and trend data reflecting the location change are written to the aggregated analytics datastore 1918.

If, alternatively, the confidence score were below the threshold or the inferred floor were the same as the current_stable_floor, the TSM module 1910 would treat the event as noise or redundancy. In that case, no state change would occur, and no updates would be propagated to the data serving layer 1904.

In parallel with the real-time flow, the ML module 1912 operates asynchronously. The TSM module 1910 provides high-confidence location data to the ML module 1912. Under an adaptive learning mode, the ML module 1912 analyzes patterns of unmapped or unknown BSSIDs observed in high-confidence events. If sufficient evidence accumulates that a previously unknown BSSID corresponds to a particular floor, the ML module 1912 generates a suggested update to the office configuration 1916, thereby enabling self-healing configuration management.

Under a predictive analytics mode, the ML module 1912 receives aggregated historical occupancy data from the aggregated analytics datastore 1918. Using this data, the ML module 1912 trains occupancy forecasting models and generates predicted occupancy values for future time intervals. These forecasts are stored in the prediction datastore 1922 within the data serving layer 1904, making them available for dashboards, planning systems, or other downstream consumers.

Accordingly, this example workflow demonstrates how telemetry 1914 events are enriched by pre-processing and enrichment 1906 using office configuration 1916 data, probabilistically evaluated by PSIE 1908, stabilized and validated by TSM 1910, and then served through the data serving layer 1904, including the aggregated analytics datastore 1918, near-real-time state store 1920, and prediction datastore 1922, with adaptive and predictive enhancements provided by the ML module 1912.

The present disclosure relates to and extends systems and methods for utilizing cloud-based telemetry to determine and recommend organization office site locations. Such systems process data from a cloud-based platform, including inline traffic logs, identity provider information, and digital experience monitoring data, to identify candidate office Internet Protocol (IP) addresses, mitigate false positives, cluster related IP addresses, triangulate geolocations using user home IP data, validate geo-accuracy, and present verified office site locations through a user interface.

While those systems determine where an organization's office sites are geographically located and assess the accuracy of those locations, the present disclosure addresses how those office sites are utilized internally, including determining floor-level occupancy and workspace utilization within a building. In various embodiments, once an office site is identified and verified using IP clustering, geo-validation, and user triangulation techniques, the systems and methods described herein operate within that validated office site boundary to provide finer-grained spatial intelligence.

Rather than relying solely on public IP geolocation, the present systems utilize Wi-Fi telemetry associated with devices, including visible wireless access points and corresponding signal strength information, to probabilistically infer a device's likely floor within a building. Thus, the previously described office site determination framework establishes a macro-level geographic boundary (e.g., identifying a specific office building in a given city), while the present disclosure provides micro-level spatial resolution within that building.

In addition, the present disclosure introduces probabilistic spatial inference, temporal state validation, and machine learning-based adaptation and forecasting techniques to enable near-real-time floor-level occupancy determination and predictive utilization analytics. The cloud-based telemetry and digital experience monitoring infrastructure described in connection with office site location determination provide the underlying data foundation upon which the present floor-level analytics operate.

Accordingly, the combined systems provide a hierarchical location intelligence architecture in which geographic office site identification and verification are complemented by intra-site, floor-level occupancy detection and predictive utilization analysis, thereby enabling comprehensive and scalable workspace intelligence using cloud-based data.

### Process for Intelligent Floor-Level Workplace Occupancy and Utilization Detection

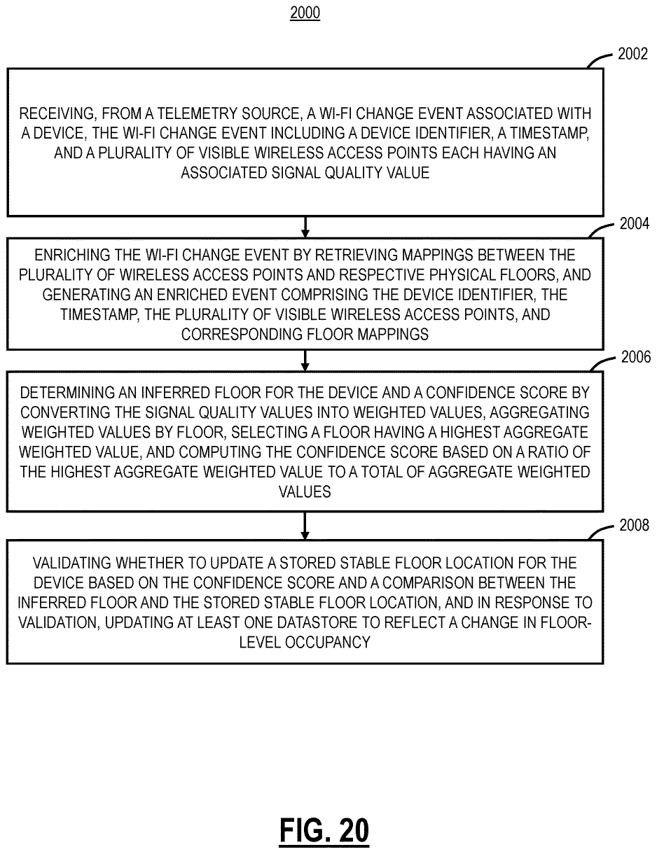

FIG. 20 is a flowchart of a process for determining floor-level workplace occupancy using network telemetry. The process 2000 includes receiving, from a telemetry source, a Wi-Fi change event associated with a device, the Wi-Fi change event including a device identifier, a timestamp, and a plurality of visible wireless access points each having an associated signal quality value (step 2002); enriching the Wi-Fi change event by retrieving mappings between the plurality of wireless access points and respective physical floors, and generating an enriched event comprising the device identifier, the timestamp, the plurality of visible wireless access points, and corresponding floor mappings (step 2004); determining an inferred floor for the device and a confidence score by converting the signal quality values into weighted values, aggregating weighted values by floor, selecting a floor having a highest aggregate weighted value, and computing the confidence score based on a ratio of the highest aggregate weighted value to a total of aggregate weighted values (step 2006); and validating whether to update a stored stable floor location for the device based on the confidence score and a comparison between the inferred floor and the stored stable floor location, and in response to validation, updating at least one data store to reflect a change in floor-level occupancy (step 2008).

The process 2000 can further include applying a non-linear weighting function to the signal quality values associated with the plurality of visible wireless access points in order to emphasize stronger signals relative to weaker signals when determining the inferred floor. In some embodiments, the non-linear weighting function includes squaring each signal quality value to generate weighted values that disproportionately favor higher-strength signals. The process 2000 can further include discarding an enriched event when the confidence score is below a predefined threshold, thereby filtering noise and preventing unstable or transient floor determinations. In certain embodiments, the stored stable floor location is updated only when the confidence score exceeds the predefined threshold and the inferred floor differs from the stored stable floor location.

The process 2000 can further include updating a near-real-time state store to increment an occupancy count for the inferred floor and decrement an occupancy count for a previously stored floor, thereby maintaining current floor-level occupancy counts. The process 2000 can additionally include storing historical occupancy data in an aggregated analytics datastore to enable trend analysis, reporting, and retrospective evaluation of workspace utilization. In some embodiments, high-confidence inferred floor determinations are provided to a machine learning module configured to identify unmapped or previously unknown wireless access points and generate suggested updates to an office configuration datastore. The machine learning module can, after accumulating sufficient high-confidence observations, update the office configuration datastore to associate a previously unmapped wireless access point with a corresponding floor.

The process 2000 can further include training a forecasting model using aggregated historical occupancy data to generate predicted future floor-level occupancy values, and storing the predicted occupancy values in a prediction datastore for access by dashboards or planning systems. In certain embodiments, the device identifier used in the process 2000 is a temporary or anonymized identifier, and floor-level occupancy is maintained in aggregated form without tracking individual user identities, thereby preserving user privacy while enabling accurate occupancy analytics.

### CONCLUSION

It will be appreciated that some embodiments described herein may include one or more generic or specialized processors (“one or more processors”) such as microprocessors; Central Processing Units (CPUs); Digital Signal Processors (DSPs): customized processors such as Network Processors (NPs) or Network Processing Units (NPUs), Graphics Processing Units (GPUs), or the like; Field Programmable Gate Arrays (FPGAs); and the like along with unique stored program instructions (including both software and firmware) for control thereof to implement, in conjunction with certain non-processor circuits, some, most, or all of the functions of the methods and/or systems described herein. Alternatively, some or all functions may be implemented by a state machine that has no stored program instructions, or in one or more Application Specific Integrated Circuits (ASICs), in which each function or some combinations of certain of the functions are implemented as custom logic or circuitry. Of course, a combination of the aforementioned approaches may be used. For some of the embodiments described herein, a corresponding device such as hardware, software, firmware, and a combination thereof can be referred to as “circuitry configured or adapted to,” “logic configured or adapted to,” etc. perform a set of operations, steps, methods, processes, algorithms, functions, techniques, etc. as described herein for the various embodiments.

Moreover, some embodiments may include a non-transitory computer-readable storage medium having computer readable code stored thereon for programming a computer, server, appliance, device, processor, circuit, etc. each of which may include a processor to perform functions as described and claimed herein. Examples of such computer-readable storage mediums include, but are not limited to, a hard disk, an optical storage device, a magnetic storage device, a ROM (Read Only Memory), a PROM (Programmable Read Only Memory), an EPROM (Erasable Programmable Read Only Memory), an EEPROM (Electrically Erasable Programmable Read Only Memory), Flash memory, and the like. When stored in the non-transitory computer readable medium, software can include instructions executable by a processor or device (e.g., any type of programmable circuitry or logic) that, in response to such execution, cause a processor or the device to perform a set of operations, steps, methods, processes, algorithms, functions, techniques, etc. as described herein for the various embodiments.

Although the present disclosure has been illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present disclosure, are contemplated thereby, and are intended to be covered by the following claims. The foregoing sections include headers for various embodiments and those skilled in the art will appreciate these various embodiments may be used in combination with one another as well as individually.

What is claimed is:

1. A method for determining floor-level workplace occupancy using network telemetry, the method comprising steps of:
receiving, from a telemetry source, a Wi-Fi change event associated with a device, the Wi-Fi change event including a device identifier, a timestamp, and a plurality of visible wireless access points each having an associated signal quality value;
enriching the Wi-Fi change event by retrieving mappings between the plurality of wireless access points and respective physical floors, and generating an enriched event comprising the device identifier, the timestamp, the plurality of visible wireless access points, and corresponding floor mappings;
determining an inferred floor for the device and a confidence score by converting the signal quality values into weighted values, aggregating weighted values by floor, selecting a floor having a highest aggregate weighted value, and computing the confidence score based on a ratio of the highest aggregate weighted value to a total of aggregate weighted values; and
validating whether to update a stored stable floor location for the device based on the confidence score and a comparison between the inferred floor and the stored stable floor location, and in response to validation, updating at least one data store to reflect a change in floor-level occupancy.

2. The method of claim 1, wherein converting the signal quality values into weighted values comprises applying a non-linear weighting function to emphasize stronger signals relative to weaker signals.

3. The method of claim 2, wherein the non-linear weighting function comprises squaring each signal quality value.

4. The method of claim 1, wherein validating comprises discarding the enriched event when the confidence score is below a predefined threshold.

5. The method of claim 1, wherein validating comprises updating the stored stable floor location only when the confidence score exceeds a predefined threshold and the inferred floor differs from the stored stable floor location.

6. The method of claim 1, further comprising updating a near-real-time state store to increment an occupancy count for the inferred floor and decrement an occupancy count for a previous floor.

7. The method of claim 1, further comprising storing historical occupancy data in an aggregated analytics datastore for trend analysis.

8. The method of claim 1, further comprising training a forecasting model using aggregated historical occupancy data and generating predicted future floor-level occupancy values.

9. The method of claim 1, wherein the device identifier is a temporary or anonymized identifier and floor-level occupancy is maintained in aggregated form without tracking individual user identities.

10. The method of claim 1, further comprising providing high-confidence inferred floor determinations to a machine learning module configured to identify unmapped wireless access points and generate suggested updates to an office configuration datastore.

11. A non-transitory computer-readable medium comprising instructions for determining floor-level workplace occupancy using network telemetry that, when executed, cause one or more processors to perform steps of:
receiving, from a telemetry source, a Wi-Fi change event associated with a device, the Wi-Fi change event including a device identifier, a timestamp, and a plurality of visible wireless access points each having an associated signal quality value;
enriching the Wi-Fi change event by retrieving mappings between the plurality of wireless access points and respective physical floors, and generating an enriched event comprising the device identifier, the timestamp, the plurality of visible wireless access points, and corresponding floor mappings;
determining an inferred floor for the device and a confidence score by converting the signal quality values into weighted values, aggregating weighted values by floor, selecting a floor having a highest aggregate weighted value, and computing the confidence score based on a ratio of the highest aggregate weighted value to a total of aggregate weighted values; and
validating whether to update a stored stable floor location for the device based on the confidence score and a comparison between the inferred floor and the stored stable floor location, and in response to validation, updating at least one data store to reflect a change in floor-level occupancy.

12. The non-transitory computer-readable medium of claim 11, wherein converting the signal quality values into weighted values comprises applying a non-linear weighting function to emphasize stronger signals relative to weaker signals.

13. The non-transitory computer-readable medium of claim 12, wherein the non-linear weighting function comprises squaring each signal quality value.

14. The non-transitory computer-readable medium of claim 11, wherein validating comprises discarding the enriched event when the confidence score is below a predefined threshold.

15. The non-transitory computer-readable medium of claim 11, wherein validating comprises updating the stored stable floor location only when the confidence score exceeds a predefined threshold and the inferred floor differs from the stored stable floor location.

16. The non-transitory computer-readable medium of claim 11, further comprising updating a near-real-time state store to increment an occupancy count for the inferred floor and decrement an occupancy count for a previous floor.

17. The non-transitory computer-readable medium of claim 11, further comprising storing historical occupancy data in an aggregated analytics datastore for trend analysis.

18. The non-transitory computer-readable medium of claim 11, further comprising training a forecasting model using aggregated historical occupancy data and generating predicted future floor-level occupancy values.

19. The non-transitory computer-readable medium of claim 11, wherein the device identifier is a temporary or anonymized identifier and floor-level occupancy is maintained in aggregated form without tracking individual user identities.

20. The non-transitory computer-readable medium of claim 11, further comprising providing high-confidence inferred floor determinations to a machine learning module configured to identify unmapped wireless access points and generate suggested updates to an office configuration datastore.
